(19) United States
(12) Patent Application Publication
(10) Pub. No.: US 2024/0072208 A1
(43) Pub. Date: Feb. 29, 2024

(54) DISPLAY APPARATUS

(71) Applicant: LG Display Co., Ltd., Seoul (KR)

(72) Inventors: Uihyeon JEONG, Paju-si (KR); Sooyoun KIM, Paju-si (KR); YongWoo LEE, Paju-si (KR); HwaYoul LEE, Paju-si (KR)

(73) Assignee: LG Display Co., Ltd., Seoul (KR)

(21) Appl. No.: 18/232,689

(22) Filed: Aug. 10, 2023

(30) Foreign Application Priority Data
Aug. 31, 2022 (KR) 10-2022-0110278

(51) Int. Cl. H01L 33/38; H01L 33/26; H01L 33/40; H01L 33/62; H10N 30/20

(52) U.S. Cl. CPC H01L 33/38; H01L 33/26; H01L 33/40; H01L 33/62; H10N 30/20; H10N 30/071

(57) ABSTRACT

A display apparatus includes a display panel having a base member, a plate member, and a display part disposed between the base member and the plate member, a vibration layer disposed at a rear surface of the plate member, and an electrode layer disposed at the vibration layer. Further, a signal cable can be provided, which is electrically coupled to the plate member and the electrode layer.

### CROSS-REFERENCE TO RELATED APPLICATIONS

This application claims priority to Korean Patent Application No. 10-2022-0110278 filed in the Republic of Korea on Aug. 31, 2022, the entire disclosure of which is hereby expressly incorporated by reference into the present application.

### BACKGROUND

### Technical Field

The present disclosure relates to a display apparatus.

### Discussion of the Related Art

Apparatuses include a display member for displaying an image and a sound apparatus for outputting a sound associated with the image displayed by the display member. In such apparatuses, a screen is progressively enlarged, but the demand for lightness and thinness is increasing.

However, since the apparatuses need to include a sufficient space where a sound apparatus such as a speaker for outputting sounds is embedded, it can be difficult to implement lightness and thinness.

Further, sounds generated by the sound apparatus embedded in an apparatus can be output in a direction toward a rear surface or a lateral surface of a main body of the apparatus instead of a front surface of the display member. Due to this, the sounds may not travel toward a viewer or a user, watching an image, of a forward region with respect to the front surface of the display member, which can cause an issue where the immersion experience of a viewer watching an image is hindered.

Moreover, a speaker applied to such apparatuses can be, for example, an actuator including a coil and a magnet. However, in a case where the actuator is applied to the apparatuses, there can be a drawback where the thickness of the apparatus can be large.

### SUMMARY OF THE DISCLOSURE

An aspect of the present disclosure is directed to providing an apparatus which can vibrate a display panel to output a sound in a forward direction of the display panel, thereby enhancing a sound.

An aspect of the present disclosure is directed to providing a display apparatus which can output a sound in a forward direction of a display panel and can be slimmed.

Additional advantages and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these and other aspects of the inventive concepts, as embodied and broadly described, a display apparatus comprises a display panel including a base member, a plate member, and a display part disposed between the base member and the plate member, a vibration layer at a rear surface of the plate member, and an electrode layer at the vibration layer.

In another aspect of the present disclosure, an apparatus comprises a display panel including a base member, a plate member, and a display part disposed between the base member and the plate member, the display panel configure to output a sound based on a vibration, a vibration member provided at the plate member, and a signal cable electrically coupled to the plate member and the vibration member.

A display apparatus according to an embodiment of the present disclosure can output a sound in a forward direction of a display panel based on a vibration of the display panel.

A display apparatus according to an embodiment of the present disclosure can output a sound in a forward direction of a display panel and can be slimmed.

A display apparatus according to an embodiment of the present disclosure can output a two-channel sound based on a vibration of a display panel.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing description and the following description of the present disclosure are examples and explanatory, and are intended to provide further explanation of the disclosures as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain principles of the disclosure.

FIG. 1 illustrates a display apparatus according to an embodiment of the present disclosure.

FIG. 2 is a cross-sectional view taken along line I-I′ illustrated in FIG. 1 according to this embodiment of the present disclosure.

FIG. 3 is a cross-sectional view illustrating one subpixel configured in a display part of FIG. 2 according to this embodiment of the present disclosure.

FIG. 4 is another example of a cross-sectional view taken along line I-I′ illustrated in FIG. 1 according to this embodiment of the present disclosure.

FIG. 5 illustrates a vibration member and a rear surface of a display panel, in a display apparatus according to an embodiment of the present disclosure.

FIG. 6 is a cross-sectional view taken along line II-II′ illustrated in FIG. 5 according to this embodiment of the present disclosure.

FIG. 7 illustrates a display apparatus according to another embodiment of the present disclosure.

FIG. 8 is a cross-sectional view taken along line III-III′ illustrated in FIG. 7 according to this embodiment of the present disclosure.

FIG. 9A illustrates a display apparatus according to another example of the present disclosure.

FIG. 9B illustrates a display apparatus according to another example of the present disclosure.

FIG. 9C illustrates a display apparatus according to another example of the present disclosure.

FIG. 9D illustrates a display apparatus according to another example of the present disclosure.

FIG. 10 illustrates a display apparatus according to another embodiment of the present disclosure.

FIG. 11 illustrates a display apparatus according to another embodiment of the present disclosure.

FIG. 12 is an enlarged view of a region ‘B1’ illustrated in FIG. 11 according to this another embodiment of the present disclosure.

FIG. 13 illustrates a vibration member and a rear surface of a display panel, in a display apparatus according to another embodiment of the present disclosure.

FIG. 14 is a cross-sectional view taken along line IV-IV′ illustrated in FIG. 13 according to this another embodiment of the present disclosure.

FIG. 15 illustrates a vibration member and a rear surface of a display panel, in a display apparatus according to another embodiment of the present disclosure.

FIG. 16 is a cross-sectional view taken along line V-V′ illustrated in FIG. 15 according to this another embodiment of the present disclosure.

FIG. 17 illustrates a vibration member and a rear surface of a display panel, in a display apparatus according to another embodiment of the present disclosure.

FIG. 18 is a cross-sectional view taken along line VI-VI′ illustrated in FIG. 17 according to this another embodiment of the present disclosure.

FIG. 19 illustrates a vibration member and a rear surface of a display panel, in a display apparatus according to another embodiment of the present disclosure.

FIG. 20 is a cross-sectional view taken along line VII-VII′ illustrated in FIG. 19 according to this another embodiment of the present disclosure.

FIG. 21 illustrates a vibration member and a rear surface of a display panel, in a display apparatus according to another embodiment of the present disclosure.

FIG. 22 is a cross-sectional view taken along line VIII-VIII′ illustrated in FIG. 21 according to this another embodiment of the present disclosure.

Throughout the drawings and the detailed description, unless otherwise described, the same drawing reference numerals should be understood to refer to the same elements, features, or structures. The sizes, lengths, and thicknesses of layers, regions and elements, and depiction thereof can be exaggerated for clarity, illustration, or convenience.

### DETAILED DESCRIPTION OF THE EMBODIMENTS

Reference is now made in detail to embodiments of the present disclosure, examples of which can be illustrated in the accompanying drawings. In the following description, where a detailed description of relevant known functions or configurations can unnecessarily obscure aspects of the present disclosure, a detailed description of such known functions or configurations can be omitted for brevity. The progression of processing steps and/or operations described is an example, and the sequence of steps and/or operations is not limited to that set forth herein and can be changed, with the exception of steps and/or operations necessarily occurring in a particular order.

Advantages and features of the present disclosure, and implementation methods thereof, are clarified through the following example embodiments described with reference to the accompanying drawings. The present disclosure may, however, be embodied in different forms and should not be construed as limited to the example embodiments set forth herein. Rather, these example embodiments are provided so that this disclosure can be sufficiently thorough and complete to assist those skilled in the art to understand the inventive concepts fully without limiting the protected scope of the present disclosure.

The shapes, dimensions, areas, ratios, angles, numbers, and the like, which are illustrated in the drawings to describe various example embodiments of the present disclosure, are merely given by way of example. Therefore, the present disclosure is not limited to the illustrations in the drawings. Like reference numerals generally denote like elements throughout the specification, unless otherwise specified.

Where a term like “comprise,” “have,” “include,” “contain,” “constitute,” “made up of,” or “formed of” is used, one or more other elements can be added unless a more limiting term, such as “only” or the like, is used. The terms and names used in the present disclosure are merely used to describe particular embodiments and are not intended to limit the scope of the present disclosure. An element described in the singular form is intended to include a plurality of elements, and vice versa, unless the context clearly indicates otherwise.

The word “exemplary” is used to mean serving as an example or illustration, unless otherwise specified. Embodiments are example embodiments. Aspects are example aspects. Any implementation described herein as an “example” is not necessarily to be construed as preferred or advantageous over other implementations.

In one or more aspects, an element, feature, or corresponding information (e.g., a level, range, dimension, size, or the like) is construed as including an error or tolerance range even where no explicit description of such an error or tolerance range is provided. An error or tolerance range can be caused by various factors (e.g., process factors, internal or external impact, noise, or the like). Further, the term “may” encompasses all the meanings of the term “can.”

In describing a positional relationship where the positional relationship between two parts is described, for example, using “on,” “over,” “under,” “above,” “below,” “beneath,” “near,” “close to,” “adjacent to,” “beside,” “next to,” “on a side of” or the like, one or more other parts can be located between the two parts unless a more limiting term, such as “immediate(ly),” “direct(ly),” or “close(ly),” is used. For example, where a structure is described as being positioned “on,” “over,” “under,” “above,” “below,” “beneath,” “near,” “close to,” “adjacent to,” “beside,” “next to” or “on a side of” another structure, this description should be construed as including a case in which the structures contact each other as well as a case in which one or more additional structures are disposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference, unless otherwise specified.

In describing a temporal relationship, where the temporal order is described as, for example, “after,” “subsequent,” “next,” “before,” “preceding,” “prior to,” or the like, a case that is not consecutive or not sequential can be included unless a more limiting term, such as “just,” “immediate(ly),” or “direct(ly),” is used.

It will be understood that, although the term “first,” “second,” or the like can be used herein to describe various elements, these elements should not be limited by these terms, for example, to any particular order, sequence, precedence, or number of elements. These terms are only used to distinguish one element from another. For example, a first element could be termed a second element, and, similarly, a second element could be termed a first element, without departing from the scope of the present disclosure. Furthermore, the first element, the second element, and the like can be arbitrarily named according to the convenience of those skilled in the art without departing from the scope of the present disclosure. The terms “first,” “second,” and the like can be used to distinguish components from each other, but the functions or structures of the components are not limited by ordinal numbers or component names in front of the components.

In describing elements of the present disclosure, the terms “first,” “second,” “A,” “B,” “(a),” “(b),” or the like can be used. These terms are intended to identify the corresponding element(s) from the other element(s), and are not used to define the essence, basis, order, or number of the elements.

Where an element or layer is described as “connected,” “coupled,” “attached,” or “adhered” to another element or layer, the element or layer can not only be directly connected, coupled, attached, or adhered to another element or layer, but also be indirectly connected, coupled, attached, or adhered to another element or layer with one or more intervening elements or layers disposed or interposed between the elements or layers, unless otherwise specified.

For the expression that an element or layer “contacts,” “overlaps,” or the like with another element or layer, the element or layer can not only directly contact, overlap, or the like with another element or layer, but also indirectly contact, overlap, or the like with another element or layer with one or more intervening elements or layers disposed or interposed between the elements or layers, unless otherwise specified.

Such terms as a “line” or “direction” should not be interpreted only based on a geometrical relationship in which the respective lines or directions are parallel or perpendicular to each other. Such terms can mean a wider range of lines or directions within which the components of the present disclosure can operate functionally.

The term “at least one” should be understood as including any and all combinations of one or more of the associated listed items. For example, the meaning of “at least one of a first item, a second item, and a third item” encompasses the combination of all three listed items, combinations of any two the first item, the second item, and the third item, as well as any individual item, the first item, the second item, or the third item.

The expression of a first element, a second elements, “and/or” a third element should be understood to encompass one of the first, second, and third elements, as well as any and all combinations of the first, second and third elements. By way of example, A, B and/or C encompass only A; only B; only C; any combination of two of A, B, and C; and all of A, B, and C. Furthermore, an expression “element A/element B” can be understood as element A and/or element B.

In one or more aspects, the terms “between” and “among” can be used interchangeably simply for convenience unless stated otherwise. For example, an expression “between a plurality of elements” can be understood as among a plurality of elements. In another example, an expression “among a plurality of elements” can be understood as between a plurality of elements. In one or more examples, the number of elements can be two. In one or more examples, the number of elements can be more than two.

In one or more aspects, the phrases “each other” and “one another” can be used interchangeably simply for convenience unless stated otherwise. For example, an expression “different from each other” can be understood as different from one another. In another example, an expression “different from one another” can be understood as different from each other. In one or more examples, the number of elements involved in the foregoing expression can be two. In one or more examples, the number of elements involved in the foregoing expression can be more than two.

In one or more aspects, the phrases “one or more among” and “one or more of” can be used interchangeably simply for convenience unless stated otherwise.

Features of various embodiments of the present disclosure can be partially or wholly coupled to or combined with each other, and can be operated, linked, or driven together in various ways. Embodiments of the present disclosure can be carried out independently from each other, or can be carried out together in a co-dependent or related relationship. In one or more aspects, the components of each apparatus according to various embodiments of the present disclosure can be operatively coupled and configured.

Unless otherwise defined, the terms (including technical and scientific terms) used herein have the same meaning as commonly understood by one of ordinary skill in the art to which example embodiments belong. It should be further understood that terms, such as those defined in commonly used dictionaries, should be interpreted as having a meaning that is, for example, consistent with their meaning in the context of the relevant art and should not be interpreted in an idealized or overly formal sense, unless expressly defined otherwise herein.

A term “apparatus” used herein may refer to a display apparatus including a display panel and a driver for driving the display panel. Examples of the display device may include a light-emitting device, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light-emitting device, but embodiments of the present disclosure are not limited thereto.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

In the following description, various example embodiments of the present disclosure are described in detail with reference to the accompanying drawings. With respect to reference numerals to elements of each of the drawings, the same elements can be illustrated in other drawings, and like reference numerals can refer to like elements unless stated otherwise. In addition, for convenience of description, a scale, dimension, size, and thickness of each of the elements illustrated in the accompanying drawings can be different from an actual scale, dimension, size, and thickness. Thus, embodiments of the present disclosure are not limited to a scale, dimension, size, or thickness illustrated in the drawings.

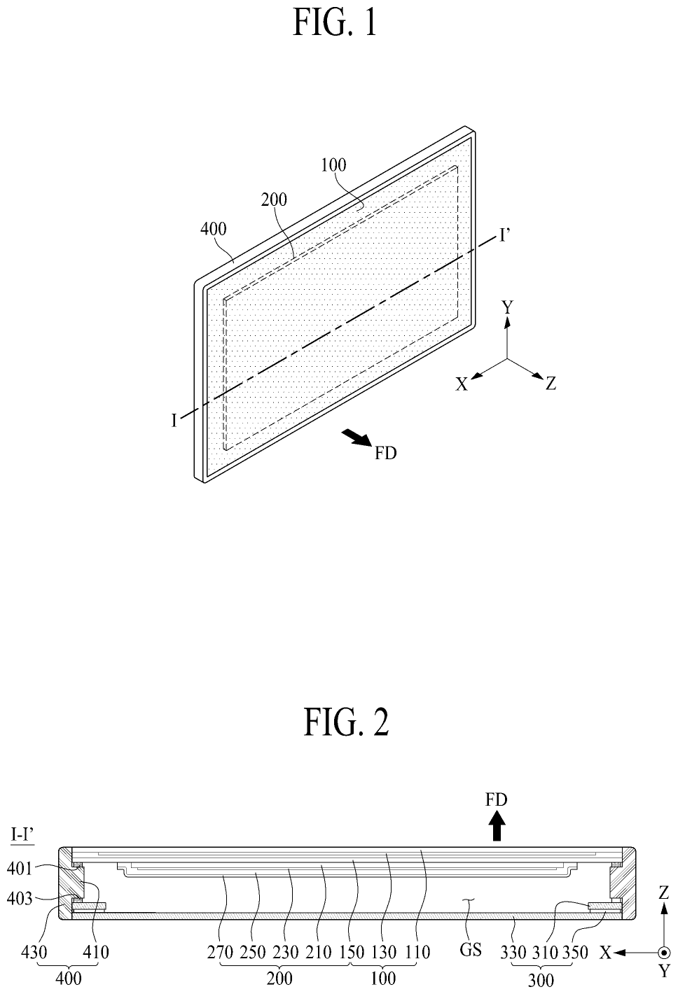

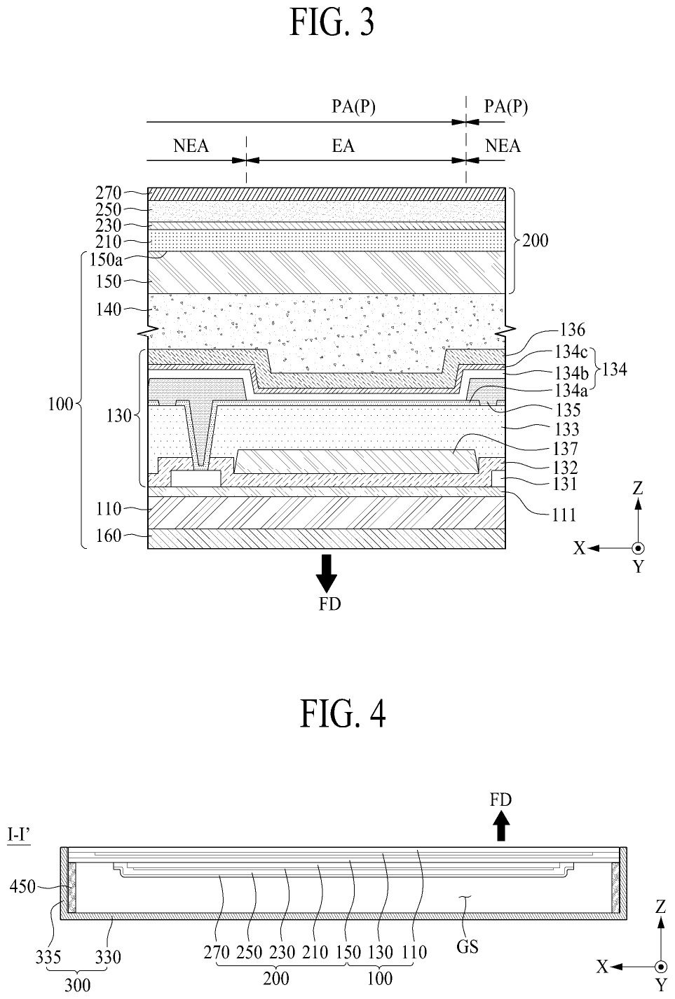

FIG. 1 illustrates a display apparatus according to an embodiment of the present disclosure. FIG. 2 is a cross-sectional view taken along line I-I′ illustrated in FIG. 1 according to the embodiment of the present disclosure. FIG. 3 is a cross-sectional view illustrating one subpixel provided in a display part of FIG. 2 according to the embodiment of the present disclosure. All the components of each display apparatus according to all embodiments of the present disclosure are operatively coupled and configured.

With reference to FIGS. 1 to 3, the display apparatus (or a light-emitting display apparatus or a flexible display apparatus) according to the embodiment of the present disclosure can include a display panel 100 and a vibration member 200.

The display panel 100 can be configured to display an image and can be configured to output a sound, based on a vibration of a plate member 150. The display panel 100 can provide a sound and/or a haptic feedback to a user, based on a vibration.

The display panel 100 can include a base member 110, a display part 130, and a plate member 150.

The base member 110 can be configured as one or more of a glass material and a plastic material. For example, the base member 110 can be configured as a polyimide material. The base member 110 can also include a stack structure of a glass layer and a plastic layer. For example, the base member 110 can be one or more of a base substrate, a first substrate, a display substrate, a front substrate, a front member, or an external substrate, but embodiments of the present disclosure are not limited thereto.

If a plastic material is used as a material of the base member 110, polyimide (PI) having heat resistance tolerable at a high temperature can be used considering that a deposition process of a high temperature is performed over the base member 110, but embodiments of the present disclosure are not limited thereto. For example, the plastic material may include any one of polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), polystyrene (PS), or the like.

A first surface (or an inner surface) of the base member 110 can fully be covered by one or more buffer layers 111.

The buffer layer 111 can prevent a material contained in the base member 110 from being diffused to a transistor layer during a high-temperature process of the fabricating process of the thin film transistor. Further, the buffer layer 111 can prevent external water or moisture from being permeated into the light-emitting device. As such, the buffer layer 111 can be configured as an inorganic material.

The display part 130 can be configured on the base member 110 or the buffer layer 111. For example, the display part 130 can be configured on the base member 110 or the buffer layer 111 to display an image.

The display part 130 can include a plurality of pixels P which display an image, based on a signal supplied to signal lines configured on the base member 110 or the buffer layer 111. For example, the display part 130 can include a pixel array part which is disposed in a pixel area provided by a plurality of gate lines and/or a plurality of data lines. The pixel array part can include a plurality of pixels configured to display an image according to signals supplied to signal lines. The signal lines can include a gate line, a data line, and a pixel driving power line, and the like, but embodiments of the present disclosure are not limited thereto.

Each of the plurality of pixels P (or a pixel area PA) can include an emission region EA and a non-emission region NEA which surrounds or which is adjacent to the emission region EA. The emission region EA can be an opening region, an emission part, or an opening part, but embodiments of the present disclosure are not limited thereto. The non-emission region NEA can be a non-emission portion or a circuit region. Each of the plurality of pixels P can be a minimum-unit region which actually emits light and can be defined as a subpixel. At least three adjacent pixels P can configure one unit pixel for displaying a color. For example, one unit pixel can include a red pixel, a green pixel, and a blue pixel adjacent to one another, and moreover, can further include a white pixel for luminance enhancement.

Each of the plurality of pixels P can be configured to display an image in a bottom emission type. Based on the bottom emission type, light emitted from a pixel P can pass through the base member 110 and can be irradiated in a rearward direction of the base member 110. Alternatively, each of the plurality of pixels P may also be configured to display an image in a top emission type or a bottom and top emission type, but not limited thereto.

Each of the plurality of pixels P according to an embodiment of the present disclosure can include a pixel circuit 131, an overcoat layer 133, and a light-emitting device layer (or a light-emitting device) 134.

The pixel circuit 131 can be configured in the non-emission region NEA of the pixel P together with the signal lines and can be connected with the gate line, the data line, and the pixel driving power line, which are adjacent thereto. The pixel circuit 131 can control a current flowing the light-emitting device layer 134 on the basis of a data signal from the data line in response to a scan pulse from the gate line, based on a pixel driving power supplied through the pixel driving power line. The pixel circuit 131 according to an embodiment of the present disclosure can include a switching thin film transistor (TFT), a driving TFT, and a capacitor, but embodiments of the present disclosure are not limited thereto.

A TFT can include a gate electrode, a gate insulating layer, a semiconductor layer, a source electrode, and a drain electrode. For example, the TFT can be an amorphous TFT, a polycrystalline TFT, an oxide TFT, or an organic TFT and the like, but embodiments of the present disclosure are not limited thereto.

The amorphous TFT may include amorphous semiconductor material. The amorphous semiconductor material may be made of amorphous silicon (a-Si), but is not limited thereto

The oxide TFT may include oxide semiconductor material. The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline may include polycrystalline semiconductor material. TFT The polycrystalline semiconductor material has a fast movement speed of carriers such as electrons and holes and thus has high mobility, and has low energy power consumption and superior reliability. The polycrystalline semiconductor may be made of polysilicon, but is not limited thereto.

The organic TFT may include organic semiconductor material.

The switching TFT can be turned on based on the scan pulse supplied through the gate line and can transfer a data signal, supplied through the data line, to the driving TFT. The capacitor can be provided in an overlap region between a gate electrode and a source electrode of the driving TFT and can store a voltage corresponding to the data signal supplied to the gate electrode of the driving TFT. The driving TFT can be turned on by a voltage supplied from the switching TFT and/or a voltage of the capacitor, and thus, can control the amount of current flowing from the pixel driving power line to the light-emitting device layer 134. For example, the driving TFT can control a data current flowing from the pixel driving power line to the light-emitting device layer 134, based on the data signal supplied from the switching TFT, and thus, can allow the light-emitting device layer 134 to emit light having brightness corresponding to the data signal.

The display apparatus according to an embodiment of the present disclosure can further include a scan driving circuit (or a gate driving circuit) provided in a non-display part at a periphery of the display part 130 of the base member 110. The scan driving circuit can generate the scan pulse, based on a gate control signal, and can supply the scan pulse to the gate line. The scan driving circuit according to an embodiment of the present disclosure can be configured with a shift register including a transistor provided in a non-display part of the base member 110 which is formed by the same process as a TFT together with a TFT of the pixel P.

The pixel circuit 131 can be covered by a passivation layer 132. For example, the passivation layer 132 can be configured on the base member 110 to cover the pixel circuit 131. The passivation layer 132 can be configured as an inorganic material, for example, the passivation layer 132 may include silicon oxide (SiOx) or silicon nitride (SiNx), but embodiments of the present disclosure are not limited thereto. For example, the passivation layer 132 can also be omitted.

The overcoat layer 133 can be configured on the base member 110 to cover the pixel circuit 131. The overcoat layer 133 can be configured to provide a flat surface on the pixel circuit 131. For example, the overcoat layer 133 can be configured as an organic material, for example, the overcoat layer 133 may include acrylic resin, epoxy resin, phenolic resin, polyamide resin, polyimide resin or the like. For example, the overcoat layer 133 can be a protection layer or a planarization layer, but the terms are not limited thereto.

The light-emitting device layer 134 can be provided on the overcoat layer 133. The light-emitting device layer 134 can include a pixel electrode 134a, a light-emitting device 134b, and a common electrode 134c.

The pixel electrode 134a (or an anode electrode) can be provided on the overcoat layer 133 which overlaps a portion of the non-emission region NEA and the entire emission region EA of each pixel area PA. For example, the pixel electrode 134a can be provided in a pattern shape. The pixel electrode 134a can be electrically connected to the driving TFT of the pixel circuit 131 through a contact hole provided at the overcoat layer 133. The pixel electrode 134a can configured at a transparent conductive material such as indium-tin-oxide (ITO) or indium-zinc-oxide (IZO). Alternatively, the pixel electrode 134a may have a multilayer structure including a transparent conductive film and an opaque conductive film having high reflective efficiency. The transparent conductive film may be made of a material having a relatively high work function value such as indium-tin-oxide (ITO) or indium-zinc-oxide (IZO), and the opaque conductive film may have a single-layer or multi-layer structure including Al, Ag, Cu, Pb, Mo, Ti or an alloy thereof. For example, the pixel electrode 134a may have a structure in which the transparent conductive film and the opaque conductive film, and the transparent conductive film are sequentially stacked, or a structure in which the transparent conductive film and the opaque conductive film are sequentially stacked, but embodiments of the present disclosure are not limited thereto.

A periphery portion of the pixel electrode 134a disposed at a portion of the non-emission region NEA of each pixel area PA can be covered by the bank layer 135. The bank layer 135 can be provided on the overcoat layer 133 to cover a periphery portion of each of the pixel circuit 131 and the pixel electrode 134a, and thus, can define (or divide) the emission region EA (or an opening region or a light extraction region) of each of the plurality of pixels P. The bank layer 135 may be made of an opaque material (e.g., black material) to prevent optical interference between adjacent pixels. In this case, the bank layer 135 may include a light blocking material made of at least one of color pigment, organic black, black ink and carbon.

The light-emitting device 134b can be formed or configured on the pixel electrode 134a. The light-emitting device 134b can be configured to directly contact the pixel electrode 134a. For example, the light-emitting device 134b can include an organic light-emitting device or an inorganic light-emitting device. For example, the light-emitting device 134b can include one of an organic light-emitting layer, an inorganic light-emitting layer, and a quantum dot light-emitting layer, or can include a stack or combination structure of an organic light-emitting layer (or an inorganic light-emitting layer) and a quantum dot light-emitting layer.

The common electrode 134c (or a cathode electrode) can be configured to be connected to the light-emitting device 134b, provided at each of the plurality of pixels P, in common. The common electrode 134c can include a metal material having a high reflectance so as to reflect light, which is emitted from the light-emitting device 134b and is incident thereon, toward the base member 110.

The light-emitting device 134b according to an embodiment of the present disclosure can be implemented so that pixels emit light of the same color (for example, white light) or emit lights of different colors (for example, red light, green light, and blue light). As an embodiment of the present disclosure, the light-emitting device 134b can have a single structure including the same color for each pixel or a stack structure including two or more structures. As another embodiment of the present disclosure, the organic light-emitting device layer can have a stack structure including two or more structures including one or more different colors for each pixel. Two or more structures including one or more different colors can be configured in one or more of blue, red, yellow-green, and green, or a combination thereof, but embodiments of the present disclosure are not limited thereto. An example of the combination can include blue and red, red and yellow-green, red and green, and red/yellow-green/green, or the like, but embodiments of the present disclosure are not limited thereto. A stack structure including two or more structures having the same color or one or more different colors can further include a charge generating layer between two or more structures. The charge generating layer can have a PN junction structure and can include an N-type charge generating layer and a P-type charge generating layer.

The light-emitting device 134b according to another embodiment of the present disclosure can include a micro light-emitting diode device which is electrically connected to the pixel electrode 134a and the common electrode 134c. The micro light-emitting diode device can be a light-emitting diode implemented as an integrated circuit (IC) type or a chip type. The micro light-emitting diode device can include a first terminal electrically connected to the pixel electrode 134a and a second terminal electrically connected to the common electrode 134c.

The display apparatus or the display part 130 according to an embodiment of the present disclosure can further include a color filter layer 137.

The color filter layer 137 can be configured between the base member 110 and the overcoat layer 133 to overlap the emission region EA of the pixel P. As an embodiment of the present disclosure, the color filter layer 137 can be disposed between the passivation layer 132 and the overcoat layer 133 to overlap the emission region EA. As another embodiment of the present disclosure, the color filter layer 137 can be disposed between the base member 110 and the buffer layer 111, or can be disposed between the buffer layer 111 and the passivation layer 132 to overlap the emission region EA.

The color filter layer 137 can include a color filter which transmits only a wavelength of a color set at each of the plurality of pixels P. For example, the color filter layer 137 can include a red color filter, a green color filter, and a blue color filter.

The display panel 100 or the display part 130 according to an embodiment of the present disclosure can further include an encapsulation layer 136.

The encapsulation layer 136 can be configured to surround or cover the display part 130. The encapsulation layer 136 can be configured to prevent external water or moisture from penetrating into a light-emitting device layer. The encapsulation layer 136 can include an inorganic material layer or an organic material layer, or can be formed in a multi-layer structure where an inorganic material layer and an organic material layer are alternately stacked.

For example, the encapsulation layer 136 can include a first inorganic encapsulation layer, a second organic encapsulation layer, and a third inorganic encapsulation layer sequentially stacked.

The first inorganic encapsulation layer and the third inorganic encapsulation layer can be formed of an inorganic material such as silicon oxide (SiOx) or silicon nitride (SiNx). The second organic encapsulation layer can be formed of an organic material such as acrylic resin, epoxy resin, phenolic resin, polyamide resin, and polyimide resin. Materials of the first inorganic encapsulation layer, the second organic encapsulation layer and the third inorganic encapsulation layer are not limited thereto.

Meanwhile, the encapsulation layer 136 is not limited to three layers, for example, the encapsulation layer 136 may include n layers alternately stacked between inorganic encapsulation layer and organic encapsulation layer (where n is an integer greater than 3). Alternatively, the encapsulation layer can also be omitted.

The display panel 100 or the display part 130 according to an embodiment of the present disclosure can further include a functional film 160.

The functional film 160 can be disposed on a second surface (or an outer surface or a light extraction surface), which is opposite to a first surface, of the base member 110. For example, the functional film 160 can be coupled or attached to the second surface of the base member 110 by a transparent adhesive member. The functional film 160 according to an embodiment of the present disclosure can include one or more of an anti-reflection layer (or an anti-reflection film), a barrier layer (or a barrier film), a touch sensing layer, and a light path control layer (or a light path control film), but embodiments of the present disclosure are not limited thereto.

The anti-reflection layer can be a polarization layer (or a polarization film) for blocking light which is reflected by a TFT and/or signal lines disposed on the base member 110 and again travels to the outside. For example, the anti-reflection layer can include a circular polarization layer (or a circular polarization film). The barrier layer can include a polymer material or a material which is low in a water transmittance, and thus, can prevent the penetration of water or oxygen from the outside. The touch sensing layer can include a touch electrode layer based on a mutual capacitance type or a self-capacitance type, and thus, can output touch data, corresponding to a user touch, through the touch electrode layer. The light path control layer can include a stacked structure where a high refraction layer and a low refraction layer are alternately stacked and can change a path of light incident from each pixel P to minimize a color shift based on a viewing angle.

The plate member 150 can be configured to cover the display part 130. The plate member 150 can be attached on the display part 130 by an adhesive member 140. The adhesive member can be configured on the base member 110 to surround the display part 130. A first surface of the plate member 150 can be coupled (or attached) to the adhesive member 140, or can be directly coupled (or attached) to the adhesive member 140. Accordingly, the display part 130 can be surrounded by the base member 110 and the adhesive member 140, and thus, can be buried or embedded between the base member 110 and the adhesive member 140. For example, a second surface 150a, which is opposite to the first surface, of the plate member 150 can be a front surface (or a screen) of the display panel 100 exposed at the outside of the display apparatus.

The plate member 150 can dissipate heat occurring at the display panel 100. The plate member 150 can protect the display part 130 or the display panel 100 from an external impact and can prevent external water or moisture from penetrating into the light-emitting device layer 134b. The plate member 150 can compensate for the stiffness of the display panel 100. For example, the plate member 150 can be a plate, a conductive plate, a conductive plate member, a heat dissipation member, a heat dissipation plate, a heat dissipation substrate, an encapsulation substrate, an encapsulation plate, a stiff plate, a second substrate, a rear substrate, a rear plate, an internal substrate, or an internal plate, but embodiments of the present disclosure are not limited thereto.

The plate member 150 according to an embodiment of the present disclosure can include a conductive material or a metal material. For example, the plate member 150 can include one or more materials of an alloy of iron and nickel, stainless steel, aluminum (Al), a magnesium (Mg), a Mg alloy, a magnesium-lithium (Mg—Li) alloy, and an Al alloy, but embodiments of the present disclosure are not limited thereto.

The adhesive member 140 can be disposed (or interposed) between the display part 130 and the plate member 150 and can facing-coupled the plate member 150 to the display part 130. For example, the adhesive member 140 can be a filler. For example, the adhesive member 140 can include a pressure sensitive adhesive (PSA), an optically cleared adhesive (OCA), or an optically cleared resin (OCR). For example, the adhesive member 140 can further include a vibration transfer medium. For example, the vibration transfer medium can decrease the loss of a vibration transferred to the base member 110. For example, the vibration transfer medium can include a piezoelectric material which is contained in or added to the adhesive member 140, but embodiments of the present disclosure are not limited thereto.

The vibration member 200 can be configured to vibrate the display panel 100 or the plate member 150. The vibration member 200 can be directly configured at the display panel 100, or can be directly connected to a rear surface of the display panel 100. For example, the vibration member 200 can be integrated as one body in the display panel 100. The display panel 100 can be a display panel with a vibration apparatus integrated therein.

The vibration member 200 can include the plate member 150 of the display panel 100. The plate member 150 of the display panel 100 can be used as an electrode of the vibration member 200. For example, the vibration member 200 can be a vibration device, a vibration apparatus, a vibrator, a vibration generator, a vibration generating apparatus, an active vibration member, a displacement device, a displacement apparatus, a sound generating device, a sound generator, a sound generating apparatus, a speaker, or a piezoelectric speaker.

The vibration member 200 according to an embodiment of the present disclosure can alternately and repeatedly contract and expand based on a piezoelectric effect to vibrate in a thickness direction Z, thereby vibrating the display panel 100 (or the plate member 150). For example, the vibration member 200 can alternately and repeatedly contract and expand based on an inverse piezoelectric effect to vibrate in the thickness direction Z, thereby directly vibrating the display panel 100 (or the plate member 150).

The vibration member 200 according to an embodiment of the present disclosure can include a first electrode 150, a vibration layer 210, and a second electrode 230.

The first electrode 150 can be configured as the plate member 150 of the display panel 100. For example, the first electrode (or the plate member) 150 can be a conductive substrate, a conductive plate, a metal electrode, an electrode member, an electrode plate, a lower electrode, a lower electrode plate, a common electrode member, or a common electrode.

The vibration layer 210 can be configured at a second surface of the first electrode 150 which is opposite to a first surface of the first electrode 150 corresponding to the first surface of the plate member 150. The vibration layer 210 can be directly formed at or directly coupled to the second surface of the first electrode 150. In the following description, the “first electrode 150” can denote a “first electrode (or a plate member) 150”.

The vibration layer 210 can include a piezoelectric material or an electroactive material which includes a piezoelectric effect. For example, the piezoelectric material can have a characteristic in which, when pressure or twisting (or bending) is applied to a crystalline structure by an external force, a potential difference occurs due to dielectric polarization caused by a relative position change of a positive (+) ion and a negative (−) ion, and a vibration is generated by an electric field based on a reverse voltage applied thereto. For example, the vibration layer 210 can be referred to as a piezoelectric layer, a piezoelectric material layer, an electroactive layer, a piezoelectric material part, an electroactive part, a piezoelectric structure, a piezoelectric ceramic, a vibration part, a vibration generating part, a displacement part, a displacement generating part, a sound generating part, or an active vibration part.

The vibration layer 210 can be configured as a ceramic-based material capable of implementing a relatively high vibration, or can be configured as a piezoelectric ceramic having a perovskite-based crystalline structure.

The piezoelectric ceramic can be configured as a single crystalline ceramic having a crystalline structure, or can be configured as a ceramic material or polycrystalline ceramic having a polycrystalline structure. A piezoelectric material including the single crystalline ceramic can include α-AlPO₄, α-SiO₂, LiNbO₃, Tb₂(MoO₄)₃, Li₂B₄O₇, or ZnO, but embodiments of the present disclosure are not limited thereto. A piezoelectric material including the polycrystalline ceramic can include a lead zirconate titanate (PZT)-based material, including lead (Pb), zirconium (Zr), and titanium (Ti), or can include a lead zirconate nickel niobate (PZNN)-based material, including lead (Pb), zirconium (Zr), nickel (Ni), and niobium (Nb), but embodiments of the present disclosure are not limited thereto. For example, the vibration layer 210 can include one or more of calcium titanate (CaTiO₃), barium titanate (BaTiO₃), and strontium titanate (SrTiO₃), without lead (Pb), but embodiments of the present disclosure are not limited thereto.

The vibration layer 210 can be configured at the second surface 150a of the plate member 150 through a process before a coupling process between the plate member 150 and the display part 130. A first surface of the vibration layer 210 can be coupled to or contact with the second surface 150a of the plate member 150. For example, the first surface of the vibration layer 210 can be electrically coupled to or electrically contact with the second surface 150a of the plate member 150.

The vibration layer 210 can include a three or more-angled polygonal shape, a circular shape, or an oval shape, and the vibration layer 210 may include a non-tetragonal shape, but embodiments of the present disclosure are not limited thereto. For example, the non-tetragonal shape can include one or more of one or more straight lines and one or more curves having a curvature, but embodiments of the present disclosure are not limited thereto.

The vibration layer 210 can be configured or implemented at the second surface 150a of the first electrode 150 through a tape casting process. For example, the vibration layer 210 can be configured at the second surface 150a of the plate member 150 by a tape casting process (or method) using a piezoelectric material on the plate member 150, in a manufacturing process of the plate member 150 or a process before the coupling process between the plate member 150 and the display part 130.

According to an embodiment of the present disclosure, the vibration layer 210 can be formed (or manufactured) through a step of preparing slurry including a piezoelectric powder (or a ceramic powder) and an additive, a step of coating (or tape casting or forming) the slurry on the second surface of the plate member 150, and a step of molding (or sintering) the coated (or formed) slurry at least once. For example, the additive added to the slurry can include a material or a substance known to those skilled in the art of a piezoelectric material composition field. For example, the additive can include one or more of a dispersant, a solvent, a binder, and a plasticizer, but embodiments of the present disclosure are not limited thereto.

According to an embodiment of the present disclosure, the binder can include a high temperature binder. For example, the binder can include a glass frit. The binder can remain in a particle state at the second surface of the plate member 150 in drying of the slurry. The binder can be changed to a liquid state when the piezoelectric particle (or the ceramic particle) grows at a molding (or sintering) temperature of the slurry and can move to an interface between the plate member 150 and a piezoelectric material, and moreover, can be solidified based on a reduction in a molding temperature and can increase a coupling force (or an adhesive force) between the plate member 150 and the piezoelectric material. For example, a content of the glass frit can be 1 wt % to 12 wt %, preferably, the content of the glass frit may be 3 wt % to 10 wt %, but embodiments of the present disclosure are not limited thereto. The glass frit can include PbO or Bi₂O₃-based material, but embodiments of the present disclosure are not limited thereto.

The vibration layer 210 according to an embodiment of the present disclosure can be configured at the second surface 150a of the first electrode 150 through a tape casting process, and thus, may not be limited to a specific shape and can include a three or more-angled polygonal shape, a circular shape, or an oval shape, and can also include a non-tetragonal shape including one or more of one or more straight lines and one or more curves having a curvature.

According to an embodiment of the present disclosure, the vibration layer 210 can overlap the display part 130 of the display panel 100. For example, the vibration layer 210 can have a size corresponding to the display part 130 of the display panel 100. For example, a size of the vibration layer 210 can be the same as or smaller than the size of the display part 130. For example, a size of the vibration layer 210 can be 0.9 to 1.1 times a size of the display part 130, preferably, a size of the vibration layer 210 may be 0.9 to 1 times a size of the display part 130, but embodiments of the present disclosure are not limited thereto. For example, a size of the vibration layer 210 can be the same as or approximately same as the display part 130 of the display panel 100, and thus, the vibration layer 210 can cover a most region of the display panel 100 and a vibration generated by the vibration layer 210 can vibrate an entire region of the display panel 100, and thus, localization of a sound can be high, and satisfaction of a user can be improved. Further, a contact area (or panel coverage) between the display panel 100 and the vibration member 200 can increase, and thus, a vibration region of the display panel 100 can increase, thereby improving a sound of a middle-low-pitched sound band generated based on a vibration of the display panel 100.

The second electrode 230 can be configured at or coupled to the second surface 210a of the vibration layer 210. Therefore, the vibration layer 210 can vibrate based on a signal (or a voltage or a vibration driving signal) applied to the second electrode (or an electrode layer) 230 and the plate member 150 of the display panel 100.

The second electrode 230 can have the same or substantially same size as the vibration layer 210, or can have a size which is smaller than the vibration layer 210. For example, the second electrode 230 can have the same shape as the vibration layer 210, but embodiments of the present disclosure are not limited thereto. For example, the second electrode 230 can be an electrode layer, an upper electrode, an upper electrode layer, an individual electrode, an individual electrode layer, a pattern electrode, or a pattern electrode layer.

According to an embodiment of the present disclosure, in order to prevent electrical short circuit between the first electrode 150 and the second electrode 230, the second electrode 230 can be formed at the other portion, except a periphery portion, of the second surface 210a of the vibration layer 210. For example, the second electrode 230 can be formed at an entire first surface, other than a periphery portion, of the vibration layer 210. For example, a distance between a lateral surface (or a sidewall) of the second electrode 230 and a lateral surface (or a sidewall) of the vibration layer 210 can be at least 0.5 mm or more. For example, the distance between the lateral surface of the second electrode 230 and the lateral surface of the vibration layer 210 can be at least 1 mm or more, but embodiments of the present disclosure are not limited thereto.

According to an embodiment of the present disclosure, the second electrode 230 can be formed of a transparent conductive material, a semitransparent conductive material, or an opaque conductive material. For example, the transparent conductive material or the semitransparent conductive material of the second electrode 230 can include indium tin oxide (ITO) or indium zinc oxide (IZO), but embodiments of the present disclosure are not limited thereto. The opaque conductive material can include gold (Au), silver (Ag), platinum (Pt), palladium (Pd), molybdenum (Mo), magnesium (Mg), carbon, or silver (Ag) including glass frit, or the like, or can be formed of an alloy thereof, but embodiments of the present disclosure are not limited thereto. For example, in order to enhance an electrical characteristic and/or a vibration characteristic of the vibration layer 210, the second electrode 230 can include silver (Ag) having a low resistivity. For example, carbon can be carbon black, ketjen black, carbon nanotube, and a carbon material including graphite, but embodiments of the present disclosure are not limited thereto.

In the second electrode 230 including silver (Ag) containing the glass frit, a content of glass frit can be about 1 wt % to about 12 wt %, preferably, a content of glass frit may be about 3 wt % to about 10 wt %, but embodiments of the present disclosure are not limited thereto. The glass frit can include PbO or Bi₂O₃-based material, but embodiments of the present disclosure are not limited thereto. Accordingly, a coupling force (or an adhesive force) between the first surface of the second electrode 230 and the second surface 210a of the vibration layer 210 can increase based on the glass frit.

The vibration layer 210 can be polarized (or poling) by a certain voltage applied to the first electrode 150 and the second electrode 230 in a certain temperature atmosphere, or a temperature atmosphere that can be changed from a high temperature to a room temperature, but embodiments of the present disclosure are not limited thereto. For example, the vibration layer 210 can alternately and repeatedly contract or expand based on an inverse piezoelectric effect according to a driving signal applied to the first electrode 150 and the second electrode 230 from the outside to vibrate. For example, the vibration layer 210 can vibrate based on a vertical-direction vibration and/or a planar direction vibration by the driving signal applied to the first electrode 150 and the second electrode 230. Accordingly, the displacement of the vibration member 200 or the display panel (or the plate member 150) can be increased or improved by contraction and/or expansion of the planar direction of vibration layer 210.

The display apparatus or the vibration member 200 according to an embodiment of the present disclosure can further include a cover member 270.

The cover member 270 can be configured to protect the vibrating layer 210 and the second electrode 230. The cover member 270 can be configured to surround or cover the vibration layer 210 and the second electrode 230. For example, the cover member 270 can be a cover film, a cover layer, a protective member, or a protective layer. For example, the cover member 270 can be a polyimide (PI) film, a polyethylene terephthalate (PET) film, a polyethylene naphthalate (PEN) film, or the like, but embodiments of the present disclosure are not limited thereto.

The cover member 270 can be connected or coupled to the second surface of the second electrode 230 by an adhesive layer 250. For example, the cover member 270 can be connected or coupled to the second electrode 230 by a film laminating process using the adhesive layer 250.

The adhesive layer 250 can be disposed between the second electrode 230 and the cover member 270. For example, the adhesive layer 250 can be configured or interposed between the first electrode 150 and the cover member 270 to wind or surround the vibration layer 210 and the second electrode 230. For example, the adhesive layer 250 can be provided or filled between the first electrode 150 and the cover member 270 to fully surround each lateral surfaces of the vibration layer 210 and the second surface of the second electrode 230. For example, the vibration layer 210 and the second electrode 230 can be embedded or built-in between the first electrode 150 and the adhesive layer 250.

The adhesive layer 250 can include an electrically insulating material which has adhesiveness and is capable of compression and decompression. For example, the adhesive layer 250 can include an epoxy resin, an acrylic resin, a silicone resin, or a urethane resin, but embodiments of the present disclosure are not limited thereto.

The vibration member 200 according to an embodiment of the present disclosure can use the plate member 150 of the display panel 100 as the first electrode 150, and thus, a separate first electrode can be omitted and the display apparatus can be slimmed by a thickness of the omitted first electrode, whereby a thickness of the display apparatus can be reduced.

The display apparatus according to an embodiment of the present disclosure can further include a supporting member 300 disposed at a rear surface of the vibration member 200 (or the plate member 150).

The supporting member 300 can be disposed at the rear surface of the display panel 100. For example, the supporting member 300 can cover a rear surface of the vibration member 200 or the display panel 100. For example, the supporting member 300 can be configured to surround lateral surfaces and the rear surface of the display panel 100.

The supporting member 300 can cover an entire rear surface of the display panel 100 with a gap space GS therebetween. The supporting member 300 can be spaced apart from a rearmost surface of the display panel 100 with a gap space GS therebetween and can be spaced apart from the vibration member 200. For example, the gap space GS can be referred to as an air gap, a vibration space, a sound resonance box, or the like, but the terms are not limited thereto.

The supporting member 300 according to an embodiment of the present disclosure can include at least one or more of a glass material, a metal material, and a plastic material. For example, the supporting member 300 can be a rear surface structure, a set structure, a supporting structure, a supporting cover, a back cover, a cover bottom, a rear member, a case, or a housing, but embodiments of the present disclosure are not limited thereto. For example, the supporting member 300 can be implemented as an arbitrary type of frame or a plate-shaped structure or the like disposed at the rear surface of the display panel 100.

The supporting member 300 according to an embodiment of the present disclosure can include a first supporting member 310 and a second supporting member 330.

The first supporting member 310 can be disposed between the display panel 100 and the second supporting member 330. For example, the first supporting member 310 can be disposed between a rear periphery portion of the display panel 100 and a front periphery portion of the second supporting member 330. The first supporting member 310 can support one or more of the rear periphery portion of the display panel 100 and the front periphery portion of the second supporting member 330. As another embodiment of present disclosure, the first supporting member 310 can cover at least a portion of the rear surface of the display panel 100. For example, the first supporting member 310 can cover the entire rear surface of the display panel 100. For example, the first supporting member 310 can include at least one or more materials of a glass material, a metal material, and a plastic material. For example, the first supporting member 310 can be an inner plate, a first rear structure, a first supporting structure, a first supporting cover, a first back cover, a first rear member, an internal plate, or an internal cover, but the terms are not limited thereto. Alternatively, the first supporting member 310 can also be omitted.

The first supporting member 310 can be spaced apart from a rearmost surface of the display panel 100 with a gap space GS therebetween or can be spaced apart from the vibration member 200.

The second supporting member 330 can be disposed at a rear surface of the first supporting member 310. The second supporting member 330 can be a member which covers the entire rear surface of the display panel 100. For example, the first supporting member 310 can be disposed between the rear surface of the vibration member 200 and the front surface of the second supporting member 330. For example, the second supporting member 330 can include at least one or more of a glass material, a metal material, and a plastic material. For example, the second supporting member 330 can be an outer plate, a rear plate, a back plate, a back cover, a rear cover, a second rear structure, a second supporting structure, a second supporting cover, a second back cover, a second rear member, an external plate, an external cover, but the terms are not limited thereto.

The supporting member 300 according to an embodiment of the present disclosure can further include a connection member (or a coupling member) 350.

The connection member 350 can be disposed between the first supporting member 310 and the second supporting member 330. For example, the first supporting member 310 and the second supporting member 330 can be coupled or connected to each other by the connection member 350. For example, the connection member 350 can be an adhesive resin, a double-sided tape, or a double-sided adhesive foam pad, but embodiments of the present disclosure are not limited thereto. For example, the connection member 350 can have elasticity for absorbing an impact, but embodiments of the present disclosure are not limited thereto. For example, the connection member 350 can be disposed at an entire region between the first supporting member 310 and the second supporting member 330. As another example embodiment of the present disclosure, the connection member 350 can be provided in a mesh structure including an air gap between the first supporting member 310 and the second supporting member 330.

The display apparatus according to an embodiment of the present disclosure can further include a middle frame 400.

The middle frame 400 can be disposed between the rear periphery portion of the display panel 100 and a front periphery portion of the supporting member 300. The middle frame 400 can support one or more of the rear periphery portion of the display panel 100 and the front periphery portion of the supporting member 300. The middle frame 400 can surround one or more of lateral surfaces of each of the display panel 100 and the supporting member 300. The middle frame 400 can be configured to provide a gap space GS between the display panel 100 and the supporting member 300. The middle frame 400 can be referred to as a middle cabinet, a middle cover, a middle chassis, a connection member, a frame, a frame member, or a side cover member, or the like, but the terms are not limited thereto.

The middle frame 400 according to an embodiment of the present disclosure can include a first supporting part 410 and a second supporting part 430. For example, the second supporting part 430 can be a sidewall part, but embodiments of the present disclosure are not limited thereto.

The first supporting part 410 can be disposed between the rear periphery portion of the display panel 100 and the front periphery portion of the supporting member 300, and thus, can provide the gap space GS between the display panel 100 and the supporting member 300. A front surface of the first supporting part 410 can be coupled or connected to the rear periphery portion of the display panel 100 by a first connection member 401. A rear surface of the first supporting part 410 can be coupled or connected to the front periphery portion of the supporting member 300 by a second connection member 403. For example, the first supporting part 410 can have a single picture frame structure having a square shape or a frame structure having a plurality of divided bar shapes, but embodiments of the present disclosure are not limited thereto.

The second supporting part 430 can be disposed in parallel with a thickness direction Z of the display apparatus or the display panel 100. For example, the second supporting part 430 can be vertically coupled to an outer surface of the first supporting part 410 in parallel with the thickness direction Z of the display panel 100. The second supporting part 430 can surround one or more of an outer surface of the display panel 100 and an outer surface of the supporting member 300, thereby protecting the outer surface of one or more of the display panel 100 and the supporting member 300. The first supporting part 410 can protrude from an inner surface of the second supporting part 430 toward the gap space GS between the display panel 100 and the supporting member 300.

The display apparatus according to an embodiment of the present disclosure can include a panel connection member (or a connection member) 450 instead of the middle frame 400 as shown in FIG. 4.

With reference to FIG. 4, the panel connection member 450 can be disposed between the rear periphery portion of the display panel 100 and the front periphery portion of the supporting member 300 and can provide the gap space GS between the display panel 100 and the supporting member 300. The panel connection member 450 can be disposed between the rear periphery portion of the display panel 100 and the front periphery portion of the supporting member 300, and thus, the panel connection member 450 can be adhered (or coupled) to each of the vibration member 200 and the supporting member 300. For example, the panel connection member 450 can be configured as a double-sided tape, a single-sided tape, or a double-sided adhesive foam pad, but embodiments of the present disclosure are not limited thereto. For example, an adhesive layer of the panel connection member 450 can include epoxy-based, acrylic-based, silicone-based, or urethane-based adhesive materials, but embodiments of the present disclosure are not limited thereto. For example, in order to minimize the vibration of the display panel 100 being transmitted to the supporting member 300, an adhesive layer of the panel connection member 450 can include the urethane-based material which has a relatively ductile characteristic compared to the acrylic-based. Accordingly, a vibration of the display panel 100 transmitted to the supporting member 300 can be minimized.

In the display apparatus according to an embodiment of the present disclosure, when the display apparatus includes a panel connection member 450 instead of a middle frame 400, the supporting member 300 can include a bending sidewall which is bent from an end (or an end portion) of the second supporting member 330 and surrounds an outer surface (or an outer sidewall) of the display panel 100. The bending sidewall according to an embodiment of the present disclosure can have a single sidewall structure or a hemming structure. The hemming structure can be a structure where end portions of an arbitrary member are bent in a curve shape and overlap each other or are spaced apart from each other in parallel. For example, in order to enhance a sense of beauty in design, the bending sidewall can include a first bending sidewall bent from one side (or an end or one end portion) of the second supporting member 330, and a second bending sidewall bent from the first bending sidewall to a region between the first bending sidewall and an outer surface of the display panel 100. The second bending sidewall can be spaced apart from an inner surface of the first bending sidewall to prevent (or minimize) contact with the inner surface of the first bending sidewall or external impact in a lateral direction from being transmitted to the outer surface of the display panel 100. Therefore, the second bending sidewall can prevent (or minimize) the outer surface of the display panel 100 from contacting an inner surface of the first bending sidewall or can prevent a lateral-direction external impact from being transferred to the outer surface of the display panel 100.

The display apparatus according to an embodiment of the present disclosure can generate a vibration sound and/or a sound by a vibration of the display panel 100 based on a vibration of the vibration member 200 configured at the plate member 150 of the display panel 100, and thus, can output a sound in a forward direction FD of the display panel 100. Further, the plate member 150 of the display panel 100 can protect the display part 130 from an external impact and can be used as an electrode of the vibration member 200, and thus, the display apparatus according to an embodiment of the present disclosure can be reduced or slimmed in thickness, based on a reduction in thickness of the vibration member 200. Accordingly, the display apparatus according to an embodiment of the present disclosure can output a sound in the forward direction FD of the display panel 100 and can be slimmed.

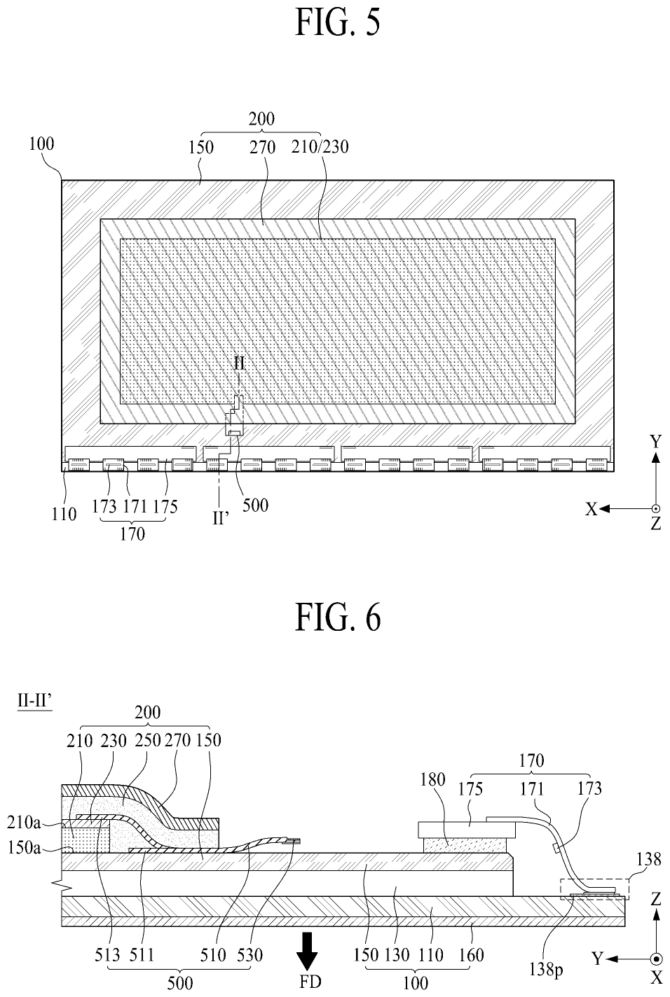

FIG. 5 illustrates a vibration member and a rear surface of a display panel, in a display apparatus according to an embodiment of the present disclosure. FIG. 6 is a cross-sectional view taken along line II-II′ illustrated in FIG. 5 according to an embodiment of the present disclosure.

With reference to FIGS. 5 and 6, the display apparatus according to an embodiment of the present disclosure can further include a panel driving circuit 170 and a signal cable 500.

The panel driving circuit 170 can be configured to electrically connected to a pad part 138 provided at the display panel 100. The panel driving circuit 170 can be disposed at a rear surface of the display panel 100 and can be electrically connected to the pad part 138 configured at the display panel 100.

The pad part 138 can be disposed at one side of the display panel 100. For example, the pad part 138 can be disposed at one periphery of the display panel 100. For example, the pad part 138 can include a plurality of pads 138p which are electrically connected to signal lines configured at the display panel 100.

The panel driving circuit 170 according to an embodiment of the present disclosure can include a plurality of flexible films 171, a plurality of data driving integrated circuits (ICs) 173, and one or more printed circuit boards (PCBs) 175.

Each of the plurality of flexible films 171 can be attached on the pad part 138 of the display panel 100 by a film attachment process. Each of the plurality of flexible films 171 can be disposed at a rear surface of the display panel 100.

Each of the plurality of data driving ICs 173 can be individually mounted on a corresponding flexible film 171 of the plurality of flexible films 171. Each of the plurality of data driving ICs 173 can receive a timing control signal and pixel data provided from a display control circuit, convert the pixel data into an analog pixel-based data signal, and output the pixel-based data signal. The pixel-based data signal can be supplied to a data line of the display part 130 through the flexible film 171 and the pad part 138.

The one or more PCBs 175 can be connected to the plurality of flexible films 171 and can be disposed at the rear surface of the display panel 100. The one or more PCBs 175 can be disposed to overlap one rear periphery portion of the display panel 100, or can be disposed to overlap the plate member 150. The one or more PCBs 175 can be configured to transfer a signal and power between elements of the panel driving circuit 170. The one or more PCBs 175 can be connected (or attached) to a second surface (or a rear surface) 500a of the plate member 150 by a buffer member 180. The buffer member 180 can include a material for blocking or minimizing the transfer of a vibration of the plate member 150 to the PCB 175. The buffer member 180 can be a double-sided tape or a double-sided cushion tape, but embodiments of the present disclosure are not limited thereto.

The signal cable 500 can be disposed at the rear surface of the display panel 100 so as to be electrically connected to the vibration member 200. For example, the signal cable 500 can be configured to be electrically connected to the vibration member 200 and the plate member 150 of the display panel 100. For example, the signal cable 500 can be configured to be electrically connected to a first electrode 150 which is a plate member of the vibration member 200 and a second electrode 230. For example, the signal cable 500 can be provided (or integrated) as one body with the vibration member 200. For example, a portion of the signal cable 500 adjacent to the vibration layer 210 can be inserted (or accommodated) into an adhesive layer 250 between the plate member 150 and the cover member 270, and thus, can be provided (or integrated) as one body with the vibration member 200. Accordingly, the vibration member 200 can vibrate based on a signal applied to the plate member 150 and the signal cable 500.

The signal cable 500 according to an embodiment of the present disclosure can include a line part 510, a first contact line 511, a second contact line 513, and a terminal part 530.

The line part 510 can be disposed at the rear surface of the display panel 100. A portion or one periphery portion of the line part 510 can be inserted (or accommodated) into the vibration member 200, or can be provided (or integrated) as one body with the vibration member 200. For example, a portion or one periphery portion of the line part 510 can be covered by the cover member 270 of the vibration member 200. For example, a portion or one periphery portion of the line part 510 can be inserted (or accommodated) into the adhesive layer 250 of the vibration member 200, and thus, can be fixed to the vibration member 200 or can be provided (or integrated) as one body with the adhesive layer 250 of the vibration member 200. Accordingly, a contact defect between the vibration member 200 and the signal cable 500 caused by the movement or bending of the signal cable 500 can be reduced or minimized.

The line part 510 can include a base film, a line layer including first and second signal lines formed at the base film, and an insulation layer covering the line layer.

The first contact line 511 can be configured to be electrically connected to (or to contact) the first electrode (or the plate member) 150 of the vibration member 200. For example, the first contact line 511 can be a portion of the first signal line exposed at one periphery portion of the line part 510, or can be a first finger line (or a first protrusion signal line) which extends (or protrudes) to have a certain length from the first signal line of the line part 510. According to an embodiment of the present disclosure, the first contact line 511 can be electrically connected to (or contact) or electrically and directly connected to (or contact) the first electrode (or the plate member) 150 of the vibration member 200. According to another embodiment of the present disclosure, the first contact line 511 can be electrically connected to (or contact) the first electrode (or the plate member) 150 of the vibration member 200 by a conductive double-sided tape or an anisotropic conductive film. The first contact line 511 can be covered by the cover member 270 of the vibration member 200, and thus, can be fixed to or integrated into the vibration member 200. Accordingly, a contact defect between the vibration member 200 and the signal cable 500 caused by the movement or bending of the signal cable 500 can be reduced or minimized.

According to an embodiment of the present disclosure, the vibration member 200 can use the plate member 150 of the display panel 100 as the first electrode 150, and thus, a contact portion (or a contact region) of the first contact line 511 and the plate member 150 is not limited to a specific position of the second surface 150a of the plate member 150. For example, the contact portion (or the contact region) of the first contact line 511 and the plate member 150 can be adjacent to the vibration layer 210 or the second electrode 230 of the vibration member 200, and thus, a length of the signal cable 500 can be reduced or minimized.

The second contact line 513 can be configured to be electrically connected to (or to contact) the second electrode 230 of the vibration member 200. The second contact line 513 can protrude onto the second electrode 230 of the vibration member 200 from one periphery portion of the line part 510. For example, the second contact line 513 can be a portion of a second signal line exposed at a protrusion line portion which protrudes onto the second electrode 230 of the vibration member 200 from the one periphery portion of the line part 510, or can be a second finger line (or a second protrusion signal line) which protrudes to have a certain length from the second signal line of the line part 510.

According to an embodiment of the present disclosure, the second contact line 513 can be electrically connected to (or contact) or electrically and directly connected to (or contact) the second electrode 230 of the vibration member 200. According to another embodiment of the present disclosure, the second contact line 513 can be electrically connected to (or contact) the second electrode 230 of the vibration member 200 by a conductive double-sided tape or an anisotropic conductive film. The second contact line 513 can be covered by the cover member 270 of the vibration member 200, and thus, can be fixed to or integrated into the vibration member 200. Accordingly, a contact defect between the vibration member 200 and the signal cable 500 caused by the movement or bending of the signal cable 500 can be reduced or minimized.

The terminal part 530 can be configured at the other periphery portion of the line part 510. The terminal part 530 can be configured to expose a portion of each of the first signal line and the second signal line disposed at the other periphery portion of the line portion 510. For example, the terminal part 530 can be electrically connected to a vibration driving circuit (or a sound processing circuit), or can include a connector which is electrically connected to the vibration driving circuit (or the sound processing circuit).

The signal cable 500 can be electrically coupled or connected to the first electrode (or the plate member) 150 and the second electrode 230, and thus, can apply or transfer first and second vibration driving signals, supplied from the vibration driving circuit through the terminal part 530, to the first electrode (or the plate member) 150 and the second electrode 230 of the vibration member 200.

The vibration member 200 according to an embodiment of the present disclosure can vibrate based on a vibration driving signal (or a sound signal) applied to the first electrode (or the plate member) 150 and the second electrode 230 through the signal cable 500, and thus, can vibrate the plate member 150 or the display panel 100.

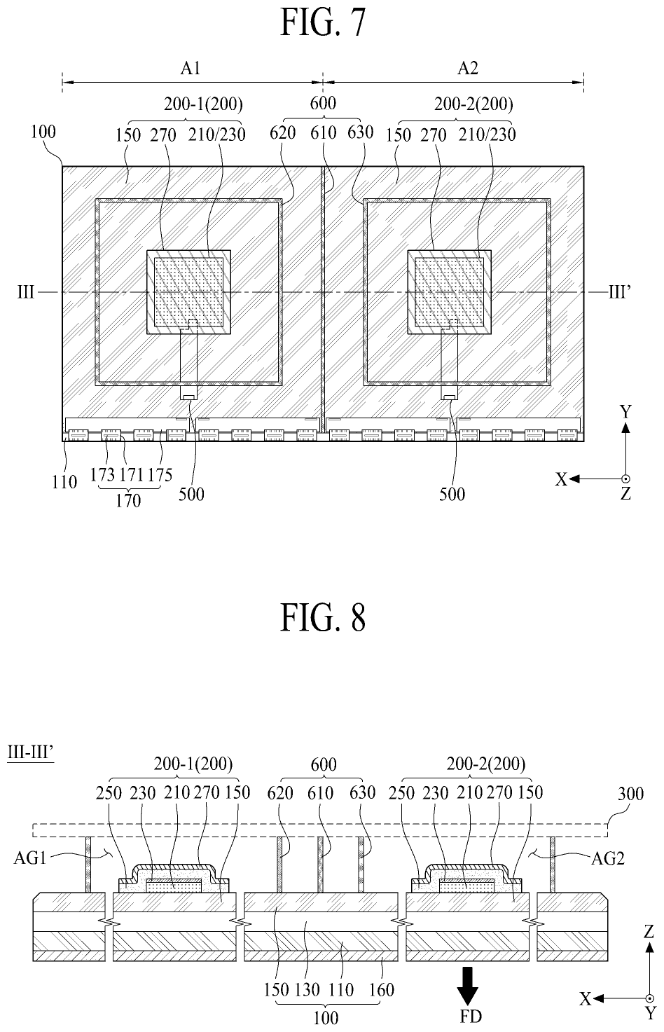

FIG. 7 illustrates a display apparatus according to another embodiment of the present disclosure. FIG. 8 is a cross-sectional view taken along line III-III′ illustrated in FIG. 7 according to an embodiment of the present disclosure. FIGS. 7 and 8 illustrate an embodiment implemented by modifying the vibration member described above with reference to FIGS. 1 to 6. In the following description, therefore, modified elements will be described in detail, the other elements are referred to by the same reference numerals as FIGS. 1 to 6, and repeated descriptions thereof can be omitted or will be briefly given.

With reference to FIGS. 7 and 8, in a display apparatus according to another embodiment of the present disclosure, a vibration member 200 can include a plurality of vibration members 200-1 and 200-2. For example, the vibration member 200 can include a first vibration member 200-1 and a second vibration member 200-2.

The first vibration member 200-1 can be configured at a first region A1 of a display panel 100. For example, the first region A1 of the display panel 100 can be a first rear region, a left region, or a left rear region. According to an embodiment of the present disclosure, the first vibration member 200-1 can be configured to have a size (or an area) which is smaller than that of the first region A1 of a display panel 100. For example, the first vibration member 200-1 can be configured to have a square shape within the first region A1 of the display panel 100, but embodiments of the present disclosure are not limited thereto. Except for that the first vibration member 200-1 is configured at the first region A1 of the display panel 100, the first vibration member 200-1 can be configured to be equal to the vibration member 200 described above with reference to FIGS. 1 to 6. For example, the first vibration member 200-1 can use the plate member 150 of the display panel 100 as a first electrode and can include a vibration layer 210 which is coupled (or configured) to a portion of the first region A1 of the plate member 150, a second electrode 230 coupled to the vibration layer 210, and a cover member 270 which covers the vibration layer 210 and the second electrode 230, and thus, repeated descriptions thereof can be omitted.

The first vibration member 200-1 can vibrate based on a signal applied through the plate member 150 and the signal cable (or a first signal cable) 500, and thus, can vibrate the first region A1 of the display panel 100. For example, the first vibration member 200-1 can vibrate based on a vibration driving signal (or a sound signal) applied to the first electrode (or the plate member) 150 and the second electrode 230 through the signal cable 500, and thus, can vibrate the first region A1 of the plate member 150 or the display panel 100. For example, the plate member 150 or the first region A1 of the display panel 100 can vibrate based on a vibration of the first vibration member 200-1, and thus, can generate a first sound (or a first haptic feedback) or a left sound (or a left haptic feedback), whereby the first sound (or the left sound) can be output in a forward direction of the display panel 100.

The second vibration member 200-2 can be configured at a second region A2 of a display panel 100. For example, the second region A2 of the display panel 100 can be a second rear region, a right region, or a right rear region. According to an embodiment of the present disclosure, the second vibration member 200-2 can be configured to have a size (or an area) which is smaller than that of the second region A2 of a display panel 100, but embodiments of the present disclosure are not limited thereto. For example, the second vibration member 200-2 can be configured to have a square shape within the second region A2 of the display panel 100. Except for that the second vibration member 200-2 is configured at the second region A2 of the display panel 100, the second vibration member 200-2 can be configured to be equal to the vibration member 200 described above with reference to FIGS. 1 to 6. For example, the second vibration member 200-2 can use the plate member 150 of the display panel 100 as a first electrode and can include a vibration layer 210 which is coupled (or configured) to a portion of the second region A2 of the plate member 150, a second electrode 230 coupled to the vibration layer 210, and a cover member 270 which covers the vibration layer 210 and the second electrode 230, and thus, repeated descriptions thereof can be omitted.

The second vibration member 200-2 can vibrate based on a signal applied through the plate member 150 and the signal cable (or a second signal cable) 500, and thus, can vibrate the second region A2 of the display panel 100. For example, the second vibration member 200-2 can vibrate based on a vibration driving signal (or a sound signal) applied to the first electrode (or the plate member) 150 and the second electrode 230 through the signal cable 500, and thus, can vibrate the second region A2 of the plate member 150 or the display panel 100. For example, the plate member 150 or the second region A2 of the display panel 100 can vibrate based on a vibration of the second vibration member 200-2, and thus, can generate a second sound (or a second haptic feedback) or a right sound (or a right haptic feedback), whereby the second sound (or the right sound) can be output in the forward direction of the display panel 100.

The plate member 150 of the display panel 100 can be used as a first electrode of each of the first vibration member 200-1 and the second vibration member 200-2 and can be supplied with a first vibration driving signal from a first signal line of the signal cable 500 connected with each of the first vibration member 200-1 and the second vibration member 200-2. For example, the first vibration driving signal can be a first sound signal, a common sound signal, a lower electrode signal, a common electrode signal, or a negative vibration signal, but the terms are not limited thereto.

The first vibration member 200-1 and the second vibration member 200-2 can be configured to be horizontally symmetric with each other with respect to a center (or a partition member 610) between the first region A1 and the second region A2 of the display panel 100, but embodiments of the present disclosure are not limited thereto and can be configured to be horizontally asymmetric.

The display apparatus according to another embodiment of the present disclosure can further include a partition 600 for dividing the first region A1 and the second region A2 of the display panel 100.

The partition 600 can be an air gap or a space, where sounds are generated when the display panel 100 is vibrated by the first and second vibration members 200-1 and 200-2. For example, the partition 600 can separate the sounds or a channel and can minimize or prevent or decrease the reduction of a sound characteristic caused by interference of the sounds. The partition 600 can be disposed at a region between the display panel 100 and the supporting member 300. For example, the partition 600 can be disposed at a region between a rear surface of the display panel 100 and a front surface of the supporting member 300. The partition 600 can be disposed at the supporting member 300 in order to minimize or reduce the effect of the image quality on the display panel 100 due to the partition 600. The partition 600 can be referred to as a sound blocking member, a sound separation member, a space separation member, an enclosure, or a baffle, or the like, but the terms are not limited thereto.

The partition 600 according to an embodiment of the present disclosure can include a partition member (or a first partition member) 610 which is disposed at a region between the first and second vibration members 200-1 and 200-2.

The partition member 610 can be disposed at a region between the first region A1 and the second region A2 of the display panel 100. The partition member 610 can be disposed at a region between the plate member 150 of the display panel 100 and the supporting member 300 between the first region A1 and the second region A2 of the display panel 100. For example, the partition member 610 can be disposed at a region between a rear surface of the plate member 150 and the supporting member 300 between the first region A1 and the second region A2 of the display panel 100. The partition member 610 can separate the first sound generated by the first vibration member 200-1 and the second sound generated by the second vibration member 200-2. For example, the partition member 610 can block the transfer of a vibration generated in the first region A1 of the display panel 100 by the first vibration member 200-1 to the second region A2 of the display panel 100, or can block the transfer of a vibration generated in the second region A2 of the display panel 100 by the second vibration member 200-2 to the first region A1 of the display panel 100. Therefore, the partition member 610 can attenuate or absorb a vibration of the display panel 100 at a center of the display panel 100, and thus, the partition member 610 can block the transfer of a sound in the first region A1 to the second region A2, or can block the transfer of a sound in the second region A2 to the first region A1. Accordingly, the partition member 610 can separate a left sound and a right sound to further enhance a sound output characteristic of the display apparatus. Thus, the display apparatus according to an embodiment of the present disclosure can output a two-channel stereo sound to the forward direction of the display panel 100 by separating the left and right sounds by the partition member 610.

The partition 600 according to an embodiment of the present disclosure can include a second partition member 620 surrounding the first vibration member 200-1 and a third partition member 630 surrounding the second vibration member 200-2.

The second partition member 620 can be disposed at a region between the first region A1 of the display panel 100 and the supporting member 300 to surround the first vibration member 200-1. The second partition member 620 can be disposed at a region between the first region A1 of the display panel 100 and the supporting member 300 to be spaced apart from the first vibration member 200-1 to have a certain distance. The second partition member 620 can form a first air gap AG1 between the display panel 100 and the supporting member 300 surrounding the first vibration member 200-1. For example, the second partition member 620 can be disposed at a region between the first region A1 of the plate member 150 corresponding to the first region A1 of the display panel 100 and the supporting member 300. For example, the second partition member 620 can define or limit a vibration region (or vibration area) of the first region A1 of the display panel 100 based on the first vibration member 200-1.

The third partition member 630 can be disposed at a region between the second region A2 of the display panel 100 and the supporting member 300 to surround the second vibration member 200-2. The third partition member 630 can be disposed at a region between the second region A2 of the display panel 100 and the supporting member 300 to be spaced apart from the second vibration member 200-2 to have a certain distance. The third partition member 630 can form a second air gap AG2 at a region between the display panel 100 and the supporting member 300 surrounding the second vibration member 200-2. For example, the third partition member 630 can be disposed at a region between the second region A2 of the plate member 150 corresponding to the second region A2 of the display panel 100 and the supporting member 300. For example, the third partition member 630 can define or limit a vibration region (or vibration area) of the second region A2 of the display panel 100 based on the second vibration member 200-2.

The first air gap AG1 and the second air gap AG2 can be referred to as a sound separation space, a sound blocking space, or a sound interference prevention space, but embodiments of the present disclosure are not limited thereto.

The second and third partition members 620 and 630 can separate the first sound generated by the first vibration member 200-1 and the second sound generated by the second vibration member 200-2. For example, the second and third partition members 620 and 630 can block the transfer of a vibration generated in the first region A1 of the display panel 100 by the first vibration member 200-1 to the second region A2 of the display panel 100, or can block the transfer of a vibration generated in the second region A2 of the display panel 100 by the second vibration member 200-2 to the first region A1 of the display panel 100. Therefore, the second and third partition members 620 and 630 can attenuate or absorb a vibration of the display panel 100, and thus, the second and third partition members 620 and 630 can block the transfer of a sound in the first region A1 to the second region A2, or can block the transfer of a sound in the second region A2 to the first region A1. Accordingly, the second and third partition members 620 and 630 can separate a left sound and a right sound to further enhance a sound output characteristic of the display apparatus. Thus, the display apparatus according to an embodiment of the present disclosure can output a stereo sound including a two-channel form or a two-channel sound to the forward direction of the display panel 100 by separating the left and right sounds according to the second and third partition members 620 and 630.

According to an embodiment of the present disclosure, each of the partition 600, the partition member 610, the second partition member 620, and third partition member 630 can be configured in a material having an elastic force that enables compression to be made to some degree, but embodiments of the present disclosure are not limited thereto. As an embodiment of the present disclosure, each of the partition 600, the partition member 610, the second partition member 620, and third partition member 630 can be configured in polyurethane or polyolefin, but embodiments of the present disclosure are not limited thereto. As another embodiment of the present disclosure, each of the partition 600, the partition member 610, the second partition member 620, and third partition member 630 can be configured as a single-sided tape, a single-sided foam pad, a double-sided tape, or a double-sided foam tape, or the like, but embodiments of the present disclosure are not limited thereto.

According to another embodiment of the present disclosure, only one of the partition member 610, the second partition member 620, and third partition member 630 can be configured. For example, even when any one of the partition member 610, the second partition member 620, and third partition member 630 is between the first vibration member 200-1 and the second vibration member 200-2, a left sound and a right sound can be separated from each other.

Therefore, the partition member 610, the second partition member 620, and third partition member 630 can separate a left sound and a right sound to further enhance a sound output characteristic of the display apparatus, and thus, a stereo sound including a two-channel form or a two-channel stereo sound by separating the left and right sounds can output in the forward direction of the display panel 100.

Like the display apparatus described above with reference to FIGS. 1 to 6, the display apparatus according to another embodiment of the present disclosure can output a sound in a forward direction FD of the display panel 100, and a thickness of the display apparatus can be reduced or slimmed. Further, the display apparatus according to another embodiment of the present disclosure can output a stereo sound including a two-channel form or a two-channel stereo sound in the forward direction of the display panel 100, based on left and right division vibrations of the display panel 100 based on vibrations of the first and second vibration members 200-1 and 200-2.

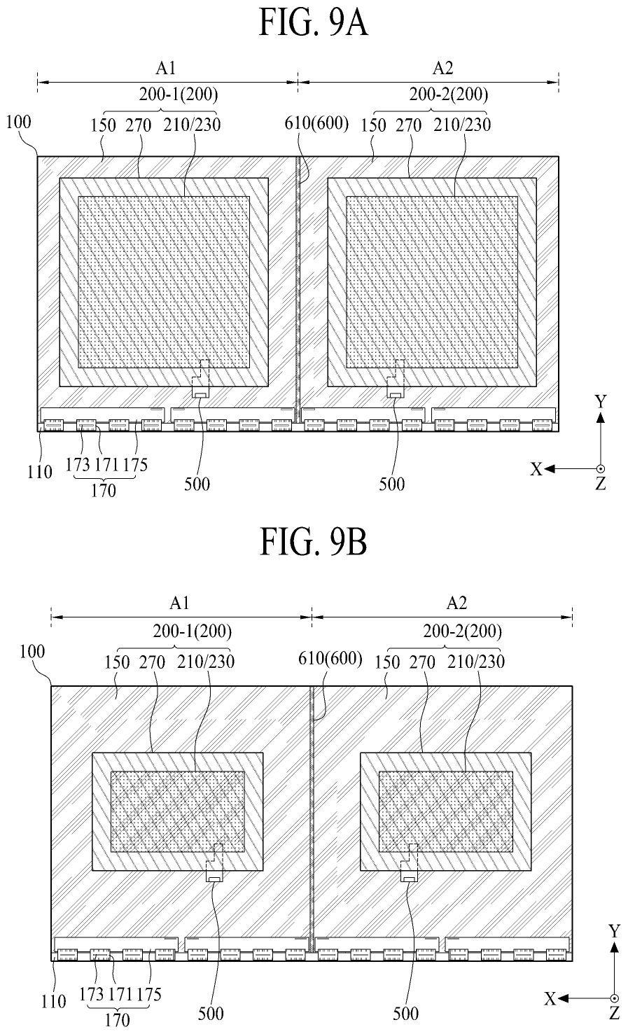

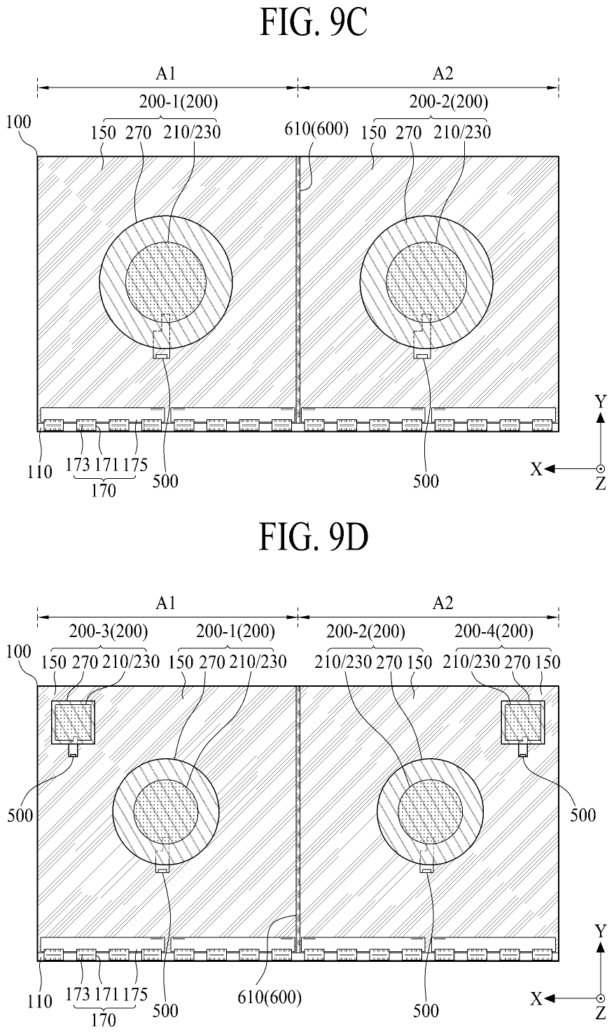

FIGS. 9A to 9D illustrate a display apparatus according to another embodiment of the present disclosure. Particularly, FIGS. 9A to 9D illustrate an embodiment implemented by modifying the vibration layer of the vibration member described above with reference to FIGS. 7 and 8. In the following description, therefore, modified elements will be described in detail, the other elements are referred to by the same reference numerals as FIGS. 7 and 8, and repeated descriptions thereof can be omitted or will be briefly given.

With reference to FIG. 9A, in a display apparatus according to another embodiment of the present disclosure, a vibration member 200 can include a first vibration member 200-1 configured at a first region A1 of a display panel 100 and a second vibration member 200-2 configured at a second region A2 of the display panel 100.

In the first vibration member 200-1, a vibration layer 210 can be configured to have a size (or an area) which is greater than half of the first region A1 of the display panel 100 and smaller than the first region A1 of the display panel 100. For example, the first vibration member 200-1 can be configured to have a square shape having a size (or an area) which is greater than half of the first region A1 and smaller than a total size of the first region A1, within the first region A1 of the display panel 100, and thus, a sound of a middle-low pitched sound band generated based on a vibration of the first region A1 of the display panel 100 can be enhanced. For example, the vibration layer 210 of the first vibration member 200-1 can be formed or coated in a square shape on a second surface of a plate member 150 corresponding to the first region A1 of the display panel 100, and then, can be molded. A second electrode 230 can be configured to have the same shape and size as those of the vibration layer 210. A cover member 270 can be configured to cover the vibration layer 210 and the second electrode 230.

In the second vibration member 200-2, a vibration layer 210 can be configured to have a size (or an area) which is greater than half of the second region A2 of the display panel 100 and smaller than the second region A2 of the display panel 100. For example, the second vibration member 200-2 can be configured to have a square shape having a size (or an area) which is greater than half of the second region A2 and smaller than a total size of the second region A2, within the second region A2 of the display panel 100, and thus, a sound of a middle-low pitched sound band generated based on a vibration of the second region A2 of the display panel 100 can be enhanced. For example, the vibration layer 210 of the second vibration member 200-2 can be formed or coated in a square shape on a second surface of a plate member 150 corresponding to the second region A2 of the display panel 100, and then, can be molded. A second electrode 230 can be configured to have the same shape and size as those of the vibration layer 210. A cover member 270 can be configured to cover the vibration layer 210 and the second electrode 230.

The first vibration member 200-1 and the second vibration member 200-2 can be configured to be horizontally symmetric with each other with respect to a center (or a partition member 610) between the first region A1 and the second region A2 of the display panel 100, but embodiments of the present disclosure are not limited thereto and can be configured to be horizontally asymmetric.

With reference to FIG. 9B, in a display apparatus according to another embodiment of the present disclosure, a vibration member 200 can include a first vibration member 200-1 configured at a first region A1 of a display panel 100 and a second vibration member 200-2 configured at a second region A2 of the display panel 100.

In a first vibration member 200-1, a vibration layer 210 can be configured to have a rectangular shape having a size (or an area) which is smaller than half of a first region A1 of a display panel 100, but embodiments of the present disclosure are not limited thereto and the vibration layer 210 can be configured to have a rectangular shape having a size (or an area) which is greater than half of the first region A1 and smaller than a total size of the first region A1 of the display panel 100. Thus, a sound of a middle-low pitched sound band generated based on a vibration of the first region A1 of the display panel 100 can be enhanced. For example, the vibration layer 210 of the first vibration member 200-1 can be formed or coated in a rectangular shape on a second surface of a plate member 150 corresponding to the first region A1 of the display panel 100, and then, can be molded. A second electrode 230 can be configured to have the same shape and size as those of the vibration layer 210. A cover member 270 can be configured to cover the vibration layer 210 and the second electrode 230.

In a second vibration member 200-2, a vibration layer 210 can be configured to have a rectangular shape having a size (or an area) which is smaller than half of a second region A2 of a display panel 100, but embodiments of the present disclosure are not limited thereto and the vibration layer 210 can be configured to have a rectangular shape having a size (or an area) which is greater than half of the second region A2 and smaller than a total size of the second region A2 of the display panel 100. Thus, a sound of a middle-low pitched sound band generated based on a vibration of the second region A2 of the display panel 100 can be enhanced. For example, the vibration layer 210 of the second vibration member 200-2 can be formed or coated in a rectangular shape on a second surface of a plate member 150 corresponding to the second region A2 of the display panel 100, and then, can be molded. A second electrode 230 can be configured to have the same shape and size as those of the vibration layer 210. A cover member 270 can be configured to cover the vibration layer 210 and the second electrode 230.

The vibration layer 210 of each of the first vibration member 200-1 and the second vibration member 200-2 can have a rectangular shape which includes a long side parallel to a first direction X (for example, a horizontal length direction of the display panel 100) and a short side parallel to a second direction Y (for example, a vertical length direction of the display panel 100) intersecting with the first direction X.

The first vibration member 200-1 and the second vibration member 200-2 can be configured to be horizontally symmetric with each other with respect to a center (or a partition member 610) between the first region A1 and the second region A2 of the display panel 100, but embodiments of the present disclosure are not limited thereto and can be configured to be horizontally asymmetric.

With reference to FIG. 9C, in a display apparatus according to another embodiment of the present disclosure, a vibration member 200 can include a first vibration member 200-1 configured at a first region A1 of a display panel 100 and a second vibration member 200-2 configured at a second region A2 of the display panel 100.

In a first vibration member 200-1, the vibration layer 210 can be configured to have a circular shape having a size (or an area) which is smaller than or equal to a first region A1 of a display panel 100, but embodiments of the present disclosure are not limited thereto and the vibration layer 210 can be configured to have a circular shape having a size (or an area) which is greater than half of the first region A1 and smaller than a total size of the first region A1. Accordingly, the vibration layer 210 can configure a vibration source (or a vibrator) having a circular shape, and thus, a vibration characteristic or a sound output characteristic can be enhanced and a sound of a middle-low pitched sound band generated based on a vibration of the first region A1 of the display panel 100 can be enhanced. For example, the vibration layer 210 of the first vibration member 200-1 can be formed or coated in a circular shape on a second surface of a plate member 150 corresponding to the first region A1 of the display panel 100, and then, can be molded. A second electrode 230 can be configured to have the same shape and size as those of the vibration layer 210. A cover member 270 can be configured to cover the vibration layer 210 and the second electrode 230.

In a second vibration member 200-2, the vibration layer 210 can be configured to have a circular shape having a size (or an area) which is smaller than or equal to a second region A2 of a display panel 100, but embodiments of the present disclosure are not limited thereto and the vibration layer 210 can be configured to have a circular shape having a size (or an area) which is greater than half of the second region A2 and smaller than a total size of the second region A2. Accordingly, the vibration layer 210 can configure a vibration source (or a vibrator) having a circular shape, and thus, a vibration characteristic or a sound output characteristic can be enhanced and a sound of a middle-low pitched sound band generated based on a vibration of the second region A2 of the display panel 100 can be enhanced. For example, the vibration layer 210 of the second vibration member 200-2 can be formed or coated in a circular shape on a second surface of a plate member 150 corresponding to the second region A2 of the display panel 100, and then, can be molded. A second electrode 230 can be configured to have the same shape and size as those of the vibration layer 210. A cover member 270 can be configured to cover the vibration layer 210 and the second electrode 230.

The first vibration member 200-1 and the second vibration member 200-2 can be configured to be horizontally symmetric with each other with respect to a center (or a partition member 610) between the first region A1 and the second region A2 of the display panel 100, but embodiments of the present disclosure are not limited thereto and can be configured to be horizontally asymmetric.

With reference to FIG. 9D, in a display apparatus according to another embodiment of the present disclosure, a vibration member 200 can include a first vibration member 200-1 and a third vibration member 200-3 configured at a first region A1 of a display panel 100 and a second vibration member 200-2 and a fourth vibration member 200-4 configured at a second region A2 of the display panel 100.

The first vibration member 200-1 and the second vibration member 200-2 can be substantially the same as the first vibration member 200-1 and the second vibration member 200-2 described above with reference to FIG. 9C, respectively, and thus, repeated descriptions thereof can be omitted.

The third vibration member 200-3 can be configured at an edge portion (or a periphery portion) of the first region A1 of the display panel 100. For example, the third vibration member 200-3 can be disposed in parallel with or disposed in a diagonal direction staggered with the first vibration member 200-1 within the first region A1 of the display panel 100. For example, the third vibration member 200-3 can be configured to be spaced apart from the first vibration member 200-1 along one direction of a first direction X, a second direction Y, and a diagonal direction between the first direction X and the second direction Y. For example, the third vibration member 200-3 can be disposed at one corner portion of the first region A1 of the display panel 100. The third vibration member 200-3 can be configured to have a size (or an area) which is smaller than the first vibration member 200-1, but embodiments of the present disclosure are not limited thereto. The third vibration member 200-3 can vibrate the edge portion (or the periphery portion) of the first region A1 of the display panel 100, and thus, can enhance a sound of a high-pitched sound band generated based on a vibration of the first region A1 of the display panel 100.

A vibration layer 210 of the third vibration member 200-3 can have a shape which is the same as or different from that of a vibration layer 210 of the first vibration member 200-1. For example, the vibration layer 210 of the third vibration member 200-3 can have a tetragonal shape or a rectangular shape which differs from that of the vibration layer 210 of the first vibration member 200-1, but embodiments of the present disclosure are not limited thereto and the vibration layer 210 of the third vibration member 200-3 can have the same circular shape as that of the vibration layer 210 of the first vibration member 200-1. For example, the vibration layer 210 of the third vibration member 200-3 can be formed or coated in a tetragonal (or a rectangular shape or a circular shape) on a second surface of a plate member 150 corresponding to the first region A1 of the display panel 100, and then, can be molded. A second electrode 230 can be configured to have the same shape and size as those of the vibration layer 210. A cover member 270 can be configured to cover the vibration layer 210 and the second electrode 230.

The fourth vibration member 200-4 can be configured at an edge portion (or a periphery portion) of the second region A2 of the display panel 100. For example, the fourth vibration member 200-4 can be disposed in parallel with or disposed in a diagonal direction staggered with the first vibration member 200-1 within the second region A2 of the display panel 100. For example, the fourth vibration member 200-4 can be configured to be spaced apart from the second vibration member 200-2 in one direction of the first direction X, the second direction Y, and the diagonal direction between the first direction X and the second direction Y. For example, the fourth vibration member 200-4 can be disposed at one corner portion of the second region A2 of the display panel 100. The fourth vibration member 200-4 can be configured to have a size (or an area) which is smaller than the second vibration member 200-2, but embodiments of the present disclosure are not limited thereto. The fourth vibration member 200-4 can vibrate the edge portion (or the periphery portion) of the second region A2 of the display panel 100, and thus, can enhance a sound of a high-pitched sound band generated based on a vibration of the second region A2 of the display panel 100.

A vibration layer 210 of the fourth vibration member 200-4 can have a shape which is the same as or different from that of a vibration layer 210 of the second vibration member 200-2. For example, the vibration layer 210 of the fourth vibration member 200-4 can have a tetragonal shape or a rectangular shape which differs from that of the vibration layer 210 of the second vibration member 200-2, but embodiments of the present disclosure are not limited thereto and the vibration layer 210 of the fourth vibration member 200-4 can have the same circular shape as that of the vibration layer 210 of the second vibration member 200-2. For example, the vibration layer 210 of the fourth vibration member 200-4 can be formed or coated in a tetragonal (or a rectangular shape or a circular shape) on a second surface of a plate member 150 corresponding to the second region A2 of the display panel 100, and then, can be molded. A second electrode 230 can be configured to have the same shape and size as those of the vibration layer 210. A cover member 270 can be configured to cover the vibration layer 210 and the second electrode 230.

The first vibration member 200-1 and the second vibration member 200-2 can be configured to be horizontally symmetric with each other with respect to a center (or a partition member 610) between the first region A1 and the second region A2 of the display panel 100, but embodiments of the present disclosure are not limited thereto and can be configured to be horizontally asymmetric. The third vibration member 200-3 and the fourth vibration member 200-4 can be configured to be horizontally symmetric with each other with respect to a center (or a partition member 610) between the first region A1 and the second region A2 of the display panel 100, but embodiments of the present disclosure are not limited thereto and can be configured to be horizontally asymmetric.

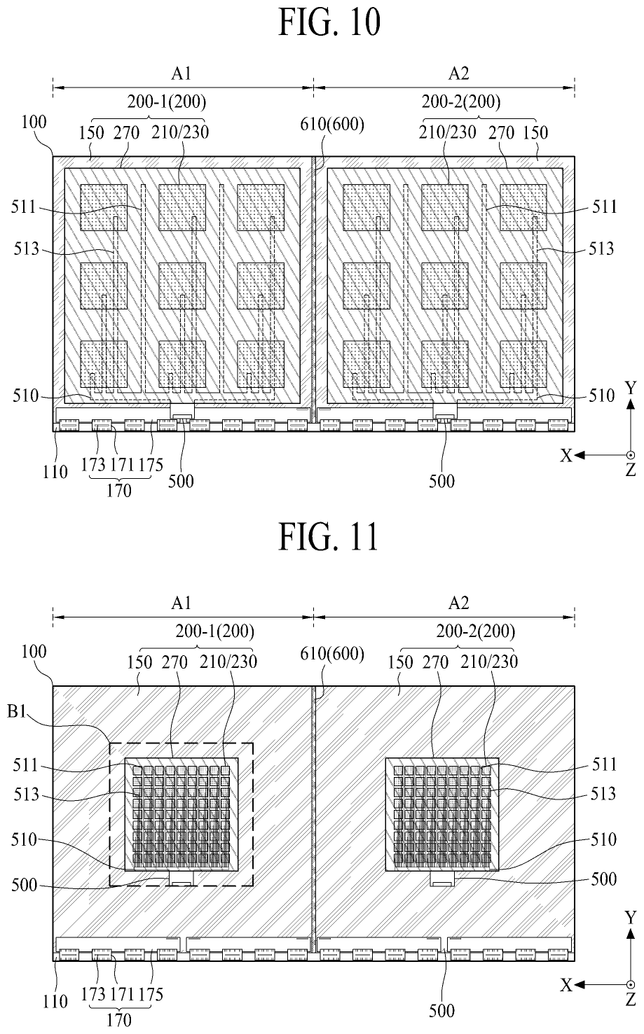

FIG. 10 illustrates a display apparatus according to another embodiment of the present disclosure. Particularly, FIG. 10 illustrates an embodiment implemented by modifying the vibration layer of the vibration member described above with reference to FIG. 9A. In the following description, therefore, modified elements will be described in detail, the other elements are referred to by the same reference numerals as FIGS. 7 to 9A, and repeated descriptions thereof may be omitted or will be briefly given.

With reference to FIG. 10, in a display apparatus according to another embodiment of the present disclosure, a vibration member 200 can include a first vibration member 200-1 configured at a first region A1 of a display panel 100 and a second vibration member 200-2 configured at a second region A2 of the display panel 100.

Each of the first vibration member 200-1 and the second vibration member 200-2 can include a plurality of vibration layers (or one or more vibration layers) 210 and a plurality of second electrodes (or one or more second electrodes) 230. Each of the first vibration member 200-1 and the second vibration member 200-2 can further include a cover member 270. Each of the first vibration member 200-1 and the second vibration member 200-2 can use a plate member 150 of the display panel 100 as a first electrode.

In each of the first vibration member 200-1 and the second vibration member 200-2, the plurality of vibration layers 210 can be configured at a second surface of a plate member 150 of the display panel 100 to have a certain interval along a first direction X and a second direction Y. For example, the plurality of vibration layers 210 can be configured in a lattice shape having the certain interval along the first direction X and the second direction Y. For example, the plurality of vibration layers 210 can be configured in an N×M (where N and M can be equal to or different from each other and can be a natural number of 2 or more) lattice shape having the certain interval along the first direction X and the second direction Y.

Each of the plurality of vibration layers 210 can include a three or more-angled polygonal shape, a non-tetragonal shape which may include one or more of one or more straight lines and one or more curves having a curvature, a circular shape, or an oval shape, but embodiments of the present disclosure are not limited thereto. For example, one or more of the plurality of vibration layers 210 can have different shapes. As an embodiment of the present disclosure, each of the plurality of vibration layers 210 can have a square shape. As another embodiment of the present disclosure, some of the plurality of vibration layers 210 can have a square shape, and the other can have a circular shape. As another embodiment of the present disclosure, the plurality of vibration layers 210 can be grouped into first to third groups. The vibration layer 210 included in the first group can have a square shape, the vibration layer 210 included in the second group can have a rectangular shape, and the vibration layer 210 included in the third group can have a circular shape. For example, when each of the first and second regions A1 and A2 of the display panel 100 includes a center region, a middle region, and an edge region (or a periphery region), the vibration layer 210 included in the first group can be configured at the center region, the vibration layer 210 included in the second group can be configured at the middle region, and the vibration layer 210 included in the third group can be configured at the edge region (or the periphery region), but embodiments of the present disclosure are not limited thereto. For example, a shape of the vibration layer 210 configured at each of the center region, the middle region, and the edge region (or the periphery region) can be changed based on a sound characteristic and/or a sound pressure level characteristic of a display apparatus.

Each of the plurality of second electrodes 230 can be configured to have the same shape and size as those of a corresponding vibration layer 210 of the plurality of vibration layers 210. The cover member 270 can be configured to cover the plurality of vibration layers 210 and the plurality of second electrodes 230 in common.

A signal cable 500 can include one or more first contact lines 511 and a plurality of second contact lines 513.

The one or more first contact lines 511 can be configured to be electrically coupled to the plate member 150. For example, the one or more first contact lines 511 can be electrically coupled to a second surface of the plate member 150 exposed at the first region A1 of the display panel 100.

The signal cable 500 can include a plurality of first contact lines 511. For example, the signal cable 500 can include two first contact lines 511. The two first contact lines 511 can extend (or protrude) long from a line part 510 along the second direction Y and can be electrically coupled to the second surface of the plate member 150, in a region between two vibration layers 210 adjacent to each other along the first direction X, and thus, a first vibration driving signal which is relatively uniform can be applied to each of the plurality of vibration layers 210.

The plurality of second contact lines 513 can be configured to be electrically coupled to the plurality of second electrodes 230. Each of the plurality of second contact lines 513 can extend (or protrude) long from the line part 510 along the second direction Y and can be electrically coupled to a corresponding second electrode 230 of the plurality of second electrodes 230.

In each of the first vibration member 200-1 and the second vibration member 200-2, each of the plurality of vibration layers 210 can identically vibrate based on the same or different second vibration driving signals, or can independently (or individually) vibrate. For example, one or more of second vibration driving signals applied to each of the plurality of vibration layers 210 can differ. Accordingly, each of the first vibration member 200-1 and the second vibration 200-2 can generate a two or more-channel sound. For example, when second vibration driving signals respectively applied to the plurality of vibration layers 210 are all different, each of the first vibration member 200-1 and the second vibration member 200-2 can generate an N×M (or N rows×M columns or N rows M columns) (where N and M may be equal to or different from each other and may be a natural number of 2 or more)-channel sound.

According to an embodiment of the present disclosure, in a plurality of vibration layers 210 arranged in a 3×3 form, (1×1)^{th} to (1×3)^{th} vibration layers 210 can configure a height channel, (2×1)^{th} to (2×3)^{th} vibration layers 210 can configure a center channel, and (3×1)^{th} to (3×3)^{th} vibration layers 210 can configure a bottom channel. Accordingly, each of the first vibration member 200-1 and the second vibration member 200-2 can generate a 3-channel sound or a horizontal 3-channel sound.

According to an embodiment of the present disclosure, in a plurality of vibration layers 210 arranged in a 3×3 form, (1×1)^{th}, (2×1)^{th}, and (3×1)^{th} vibration layers 210 can configure a left channel, (1×2)^{th}, (2×2)^{th}, and (3×2)^{th} vibration layers 210 can configure a center channel, and (1×3)^{th}, (2×3)^{th}, and (3×3)^{th} vibration layers 210 can configure a right channel. Accordingly, each of the first vibration member 200-1 and the second vibration member 200-2 can generate a 3-channel sound or a vertical 3-channel sound.

The first vibration member 200-1 and the second vibration member 200-2 can be configured to be horizontally symmetric with each other with respect to a center (or a partition member 610) between the first region A1 and the second region A2 of the display panel 100, but embodiments of the present disclosure are not limited thereto and can be configured to be horizontally asymmetric.

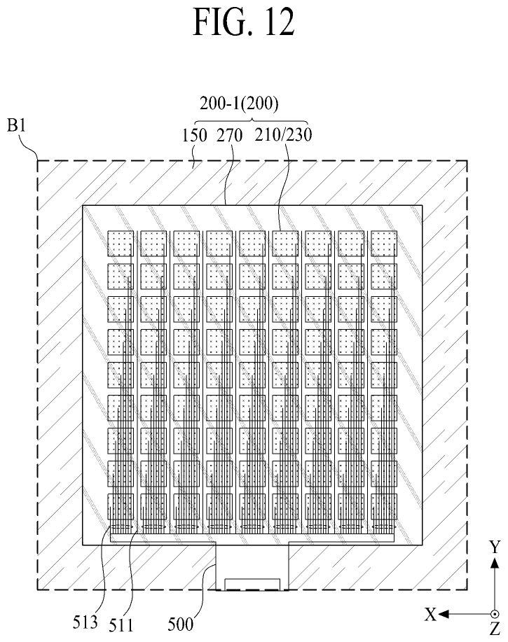

FIG. 11 illustrates a display apparatus according to another embodiment of the present disclosure. FIG. 12 is an enlarged view of a region ‘B’ illustrated in FIG. 11 according to another embodiment of the present disclosure. Particularly, FIGS. 11 and 12 illustrate an embodiment implemented by modifying the vibration layer of the vibration member described above with reference to FIGS. 7 to 9A and 10. In the following description, therefore, modified elements will be described in detail, the other elements are referred to by the same reference numerals as FIGS. 7 to 9A and 10, and repeated descriptions thereof can be omitted or will be briefly given.

With reference to FIGS. 11 and 12, in a display apparatus according to another embodiment of the present disclosure, a vibration member 200 can include a first vibration member 200-1 configured at a first region A1 of a display panel 100 and a second vibration member 200-2 configured at a second region A2 of the display panel 100.

Each of the first vibration member 200-1 and the second vibration member 200-2 can include a plurality of vibration layers (or one or more vibration layers) 210 and a plurality of second electrodes (or one or more second electrodes) 230. Each of the first vibration member 200-1 and the second vibration member 200-2 can further include a cover member 270. Each of the first vibration member 200-1 and the second vibration member 200-2 can use a plate member 150 of the display panel 100 as a first electrode.

In each of the first vibration member 200-1 and the second vibration member 200-2, a plurality of vibration layers 210 can be substantially the same as the plurality of vibration layers 210 described above with reference to FIG. 10, except for a size (or an area), and thus, repeated descriptions thereof can be omitted or will be briefly given below. For example, the plurality of vibration layers 210 can be configured in an N×M (where N and M can be equal to or different from each other and can be a natural number of 2 or more) lattice shape having a certain interval along a first direction X and a second direction Y. The descriptions of the plurality of vibration layers 210 described above with reference to FIG. 10 can be included in descriptions of the vibration layers 210 illustrated in FIGS. 11 and 12.

Each of the plurality of vibration layers 210 can be configured to have a size (or an area) which enables the plurality of vibration layers 210 not to be damaged or broken down even when the display panel 100 is bent or curved to have a certain curvature radium. For example, each of the plurality of vibration layers 210 can be a micro vibration layer.

Each of the plurality of second electrodes 230 can be configured to have the same shape and size as those of a corresponding vibration layer 210 of the plurality of vibration layers 210. The cover member 270 can be configured to cover the plurality of vibration layers 210 and the plurality of second electrodes 230 in common.

The signal cable 500 can include one or more first contact lines 511 electrically coupled to the plate member 150 and a plurality of second contact lines 513 electrically coupled to each of a plurality of second electrodes 230. This can be the same as the signal cable 500 described above with reference to FIG. 10, and thus, repeated descriptions thereof can be omitted.

In each of the first vibration member 200-1 and the second vibration member 200-2, each of the plurality of vibration layers 210 can identically vibrate based on the same or different second vibration driving signals, or can independently (or individually) vibrate. For example, one or more of second vibration driving signals applied to each of the plurality of vibration layers 210 can differ. Accordingly, each of the first vibration member 200-1 and the second vibration 200-2 can generate a two or more-channel sound. For example, when second vibration driving signals respectively applied to the plurality of vibration layers 210 are all different, each of the first vibration member 200-1 and the second vibration member 200-2 can generate an N×M-channel sound.

The first vibration member 200-1 and the second vibration member 200-2 can be configured to be horizontally symmetric with each other with respect to a center (or a partition member 610) between the first region A1 and the second region A2 of the display panel 100, but embodiments of the present disclosure are not limited thereto and can be configured to be horizontally asymmetric.

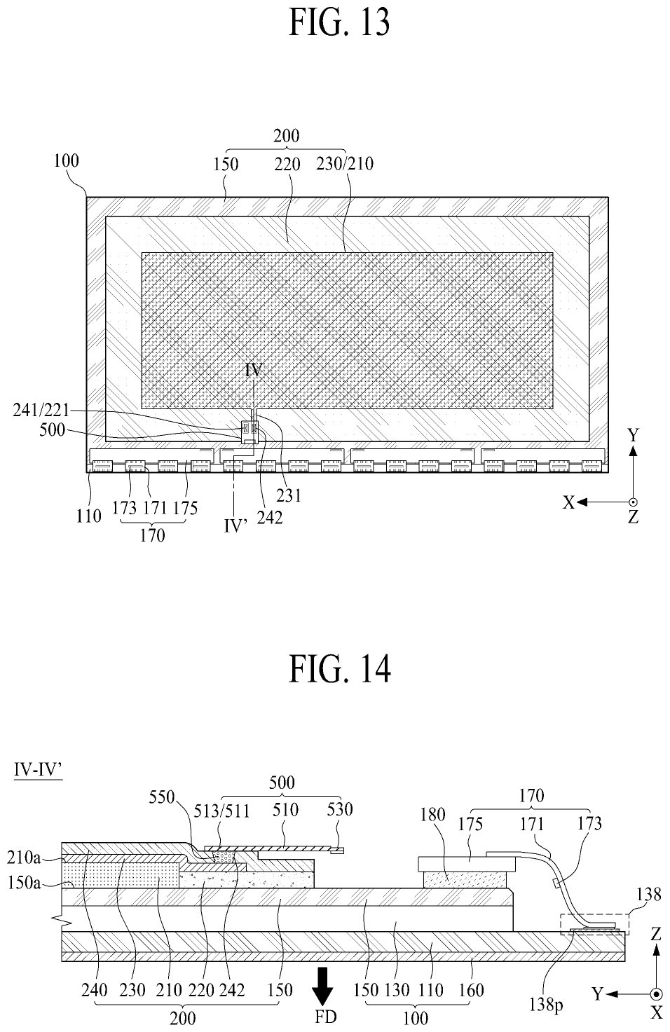

FIG. 13 illustrates a vibration member and a rear surface of a display panel, in a display apparatus according to another embodiment of the present disclosure. FIG. 14 is a cross-sectional view taken along line IV-IV′ illustrated in FIG. 13 according to another embodiment of the present disclosure. Particularly, FIGS. 13 and 14 illustrate an embodiment implemented by modifying the vibration member described above with reference to FIGS. 1 to 6. In the following description, therefore, modified elements will be described in detail, the other elements are referred to by the same reference numerals as FIGS. 1 to 6, and repeated descriptions thereof can be omitted or will be briefly given.

With reference to FIGS. 13 and 14, a vibration member 200 of the display apparatus according to another embodiment of the present disclosure can include a vibration layer 210, an insulation layer 220, a second electrode 230, and a protection layer 240.

The vibration member 200 can use a plate member 150 of a display panel 100 as a first electrode. For example, the plate member 150 of the display panel 100 can function as a first electrode of the vibration member 200.

The vibration layer 210 can be configured at the plate member 150 of the display panel 100 and can be substantially the same as the vibration layer 210 described above with reference to FIGS. 1 to 6, and thus, repeated descriptions thereof can be omitted.

The insulation layer 220 can be disposed at a second surface 150a of the plate member 150 at a periphery of (or around) the vibration layer 210. For example, the insulation layer 220 can be disposed at the second surface 150a of the plate member 150 to surround each lateral surfaces of the vibration layer 210. For example, the insulation layer 220 can be disposed at a portion or an entire of the other portion, except a disposition region of the vibration layer 210, of the second surface 150a of the plate member 150.

The insulation layer 220 can be provided to have a thickness which is smaller than that of the vibration layer 210. An uppermost surface of the insulation layer 220 can be disposed under an uppermost surface of the vibration layer 210, or can be disposed to be closer to the plate member 150 than the uppermost surface of the vibration layer 210. For example, when the insulation layer 220 has a thickness which is higher than or equal to the vibration layer 210, the uppermost surface (or a second surface) of the vibration layer 210 can be polluted in a process of forming the insulation layer 220, and thus, in order to prevent the occurrence of pollution, the insulation layer 220 can be formed to have a thickness which is smaller than that of the vibration layer 210. For example, the insulation layer 220 can include an organic material or an inorganic material. For example, the insulation layer 220 may include an organic material such as acrylic resin, epoxy resin, phenolic resin, polyamide resin, or polyimide resin, or the insulation layer 220 may include an inorganic material such as silicon oxide (SiOx) or silicon nitride (SiNx).

The insulation layer 220 can include an exposure hole 221 (see FIG. 16) for exposing a portion of the plate member 150. The exposure hole 221 can be formed by removing the insulation layer 220 disposed at a portion of the plate member 150. According to an embodiment of the present disclosure, the exposure hole 221 can be formed by removing a portion of the insulation layer 220 disposed at a periphery of (or around) the vibration layer 210.

The second electrode 230 can be configured at or coupled to a second surface 210a of the vibration layer 210. The second electrode 230 can have the same size as that of the vibration layer 210, or can have a size which is smaller than that of the vibration layer 210.

The vibration member 200 or the second electrode 230 can further include an extension line (or one or more extension lines) 231.

The extension line 231 can protrude or extend from one side of the second electrode 230 onto the insulation layer 220 adjacent to the exposure hole 221. The extension line 231 can be formed on the insulation layer 220 together with the second electrode 230 formed at the second surface 210a of the vibration layer 210. An end of the extension line 231 can be disposed in parallel with the exposure hole 221. For example, the extension line 231 can be an extension electrode, a protrusion line, an extension electrode, or a protrusion electrode, but the terms are not limited thereto.

The protection layer 240 can be configured to protect the insulation layer 220 and the second electrode 230. For example, the protection layer 240 can be configured to protect the vibration member 200. For example, the protection layer 240 can be provided to cover all of the other portion, except one edge (or periphery) portion adjacent to a pad part of the display panel 100, of the second surface 150a of the plate member 150. For example, the protection layer 240 can include an organic material or an inorganic material. For example, the protection layer 240 can include the same material as that of the insulation layer 220, for example, the protection layer 240 may include an organic material such as acrylic resin, epoxy resin, phenolic resin, polyamide resin, or polyimide resin, or the protection layer 240 may include an inorganic material such as silicon oxide (SiOx) or silicon nitride (SiNx), but embodiments of the present disclosure are not limited thereto.

The protection layer 240 can include a first hole 241 and a second hole 242. For example, the protection layer 240 can include a first hole 241 and a second hole 242, which are configured in parallel with each other.

The first hole 241 can be formed at the protection layer 240 to overlap the exposure hole 221 disposed at the insulation layer 220. The first hole 241 can be formed to expose a portion of the plate member 150 overlapping the exposure hole 221. The first hole 241 can be formed to pass through all of the insulation layer 220 and the protection layer 240 overlapping a portion of the plate member 150, and thus, a portion of the plate member 150 can be exposed at the outside of the protection layer 240. Alternatively, the exposure hole 221 formed at the insulation layer 220 can be omitted, or a process of forming the exposure hole 221 at the insulation layer 220 can be omitted. For example, the first hole 241 can be a first electrode contact hole, a first signal line contact hole, or a first line contact hole, but the terms are not limited thereto.

The second hole 242 can be formed at the protection layer 240 so as to be adjacent to the first hole 241. The second hole 242 can be formed to expose a portion of the extension line 231 of the second electrode 230. The second hole 242 can be formed to pass through the protection layer 240 overlapping a portion of the extension line 231 of the second electrode 230, and thus, a portion of the extension line 231 of the second electrode 230 can be exposed at the outside of the protection layer 240. For example, the second hole 242 can be a second electrode contact hole, a second signal line contact hole, or a second line contact hole, but the terms are not limited thereto.

A portion, where the first hole 241 and the second hole 242 are formed, of the protection layer 240 can be a pad part of the vibration member 200. The pad part of the vibration member 200 can be electrically coupled to the signal cable 500. For example, the pad part of the vibration member 200 can be disposed at a peripheral region of the vibration member 200 which does not overlap the vibration layer 210. For example, the pad part of the vibration member 200 can be configured at a position, which is easy to perform a coupling process on the signal cable 500, of a rear surface of the display panel 100.

The signal cable 500 can include a line part 510, a first contact line 511, a second contact line 513, and a terminal part 530.

The line part 510 can be disposed at the rear surface of the display panel 100 and can be disposed on the protection layer 240 of the vibration member 200. The line part 510 can include a base film, a line layer including first and second signal lines formed at the base film, and an insulation layer covering the line layer.

The first contact line 511 can be configured to be electrically connected to (or to contact) a first electrode (or the plate member) 150 of the vibration member 200. For example, the first contact line 511 can be a portion of the first signal line exposed at one periphery portion of the line part 510. The first contact line 511 can be electrically connected to (or contact) a first electrode (or the plate member) 150 of the vibration member 200 through the first hole 241. For example, the first hole 241 of the protection layer 240 can be configured at a region between a portion of the first electrode (or the plate member) 150 and the first contact line 511. For example, the first contact line 511 can be electrically connected to (or contact) the first electrode (or the plate member) 150 of the vibration member 200 through a conductive material filled into the first hole 241 of the protection layer 240. For example, the first contact line 511 can be electrically connected to (or contact) the first electrode (or the plate member) 150 of the vibration member 200 by an anisotropic conductive film including conductive piezoelectric particles 550 (see FIG. 16) filled into the first hole 241.

The second contact line 513 can be configured to be electrically connected to (or to contact) a second electrode 230 of the vibration member 200. For example, the second contact line 513 can be configured to be electrically connected to (or to contact) the extension line 231 of the second electrode 230. For example, the second contact line 513 can be a portion of a second signal line exposed at one periphery portion of the line part 510. The second contact line 513 can be electrically connected to (or contact) the extension line 231 of the second electrode 230 through the second hole 242. For example, the second hole 242 of the protection layer 240 can be configured at a region between a portion of the extension line 231 of the second electrode 230 and the second contact line 513. For example, the second contact line 513 can be electrically connected to (or contact) the extension line 231 of the second electrode 230 through a conductive material filled into the second hole 242 of the protection layer 240. For example, the second contact line 513 can be electrically connected to (or contact) the extension line 231 of the second electrode 230 by an anisotropic conductive film including conductive piezoelectric particles 550 filled into the second hole 242.

The terminal part 530 can be configured at the other periphery portion of the line part 510.

The signal cable 500 can be electrically coupled to the first electrode (or the plate member) 150 and the second electrode 230, and thus, can apply or transfer first and second vibration driving signals, supplied from the vibration driving circuit through the terminal part 530, to the first electrode (or the plate member) 150 and the second electrode 230 of the vibration member 200.

The vibration member 200 described above with reference to FIGS. 7 to 12 can be identically applied to the vibration member 200 described above with reference to FIGS. 13 and 14. For example, the vibration member 200 described above with reference to FIGS. 13 and 14 can be configured to be equal to the vibration member 200 described above with reference to FIGS. 7 to 12, and thus, repeated descriptions thereof can be omitted.

As described above, like the display apparatus described above with reference to FIGS. 1 to 6, the display apparatus according to another embodiment of the present disclosure can output a sound in a forward direction FD of the display panel 100, and a thickness of the display apparatus can be reduced or slimmed. Further, in the display apparatus according to another embodiment of the present disclosure, the pad part of the vibration member 200 can be disposed in a peripheral region, which does not overlap the vibration layer 210, of the vibration member 200, and thus, a coupling process between the pad part of the vibration member 200 and the signal cable 500 can be easily performed.

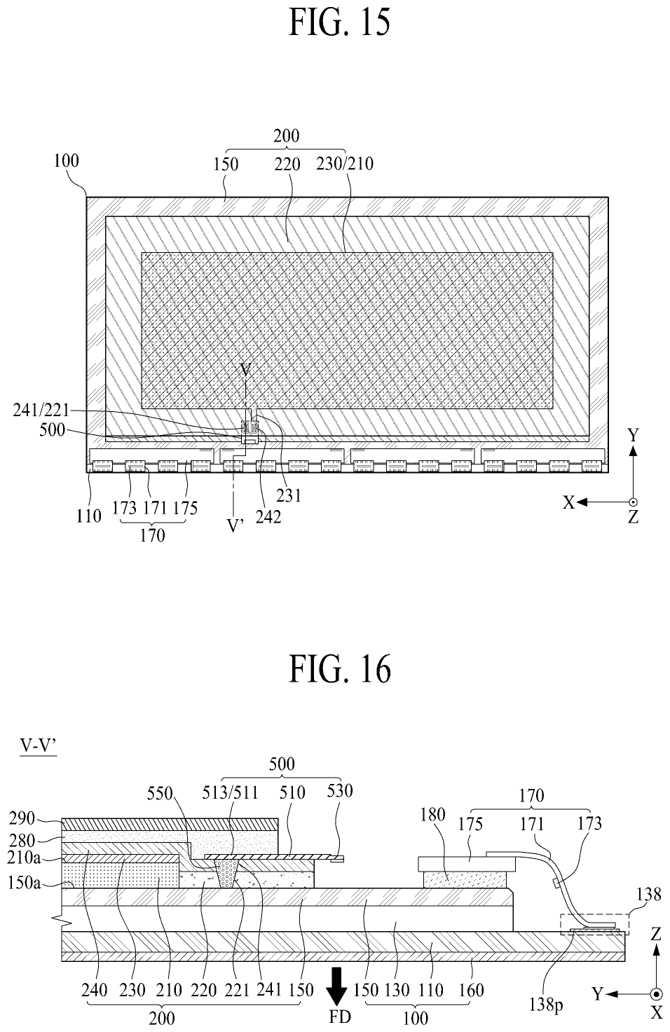

FIG. 15 illustrates a vibration member and a rear surface of a display panel, in a display apparatus according to another embodiment of the present disclosure. FIG. 16 is a cross-sectional view taken along line V-V′ illustrated in FIG. 15 according to another embodiment of the present disclosure. Particularly, FIGS. 15 and 16 illustrate an embodiment where a cover member is further configured in the vibration member or the display apparatus described above with reference to FIGS. 13 and 14. In the following description, therefore, added elements will be described in detail, while the other elements are referred to by the same reference numerals as FIGS. 13 and 14, and repeated descriptions thereof can be omitted or will be briefly given.

With reference to FIGS. 15 and 16, a display apparatus or a vibration member 200 according to another embodiment of the present disclosure can further include a cover member 290.

The cover member 290 can be configured to cover a portion of the signal cable 500 and the protection layer 240 of the vibration member 200. The cover member 290 can be configured to surround or cover the protection layer 240 of the vibration member 200 and the other portion, except the terminal part 530, of the signal cable 500. For example, the cover member 290 can be a cover film, a cover layer, a protective member, or a second protective layer, but the terms are not limited thereto. For example, the cover member 290 can be a polyimide (PI) film, a polyethylene terephthalate (PET) film, or a polyethylene naphthalate (PEN) film, but embodiments of the present disclosure are not limited thereto.

The cover member 290 can be connected or coupled to a portion of the signal cable 500 and the protection layer 240 of the vibration member 200 by an adhesive layer 280. The cover member 290 can be connected or coupled to a portion of the signal cable 500 and the protection layer 240 of the vibration member 200 by a film laminating process using the adhesive layer 280. Accordingly, a portion of the signal cable 500 can be buried or embedded between the protection layer 240 of the vibration member 200 and the adhesive layer 280 (or the cover member 290), and thus, can be integrated into or fixed to the vibration member 200.

The adhesive layer 280 can include an electrically insulating material which has adhesiveness and is capable of compression and decompression. For example, the adhesive layer 280 can include an epoxy resin, an acrylic resin, a silicone resin, or a urethane resin, but embodiments of the present disclosure are not limited thereto.

The vibration member 200 described above with reference to FIGS. 7 to 12 can be substantially identically applied to the vibration member 200 described above with reference to FIGS. 15 and 16. For example, the vibration member 200 described above with reference to FIGS. 15 and 16 can include a first vibration member 200-1 and a second vibration member 200-2 of the vibration member 200 described above with reference to FIGS. 7 to 12, and thus, repeated descriptions thereof can be omitted.

As described above, like the display apparatus described above with reference to FIGS. 13 and 16, the display apparatus according to another embodiment of the present disclosure can output a sound in a forward direction FD of the display panel 100, a thickness thereof can be reduced or slimmed, and a coupling process between the pad part of the vibration member 200 and the signal cable 500 can be easily performed. Further, the display apparatus according to another embodiment of the present disclosure can include a cover member 290 which covers a portion of the signal cable 500 and the protection layer 240 of the vibration member 200, and thus, the vibration member 200 can be protected from an external impact and a connection defect between the pad part of the vibration member 200 and the signal cable 500 caused by the movement or bending of the signal cable 500 can be minimized.

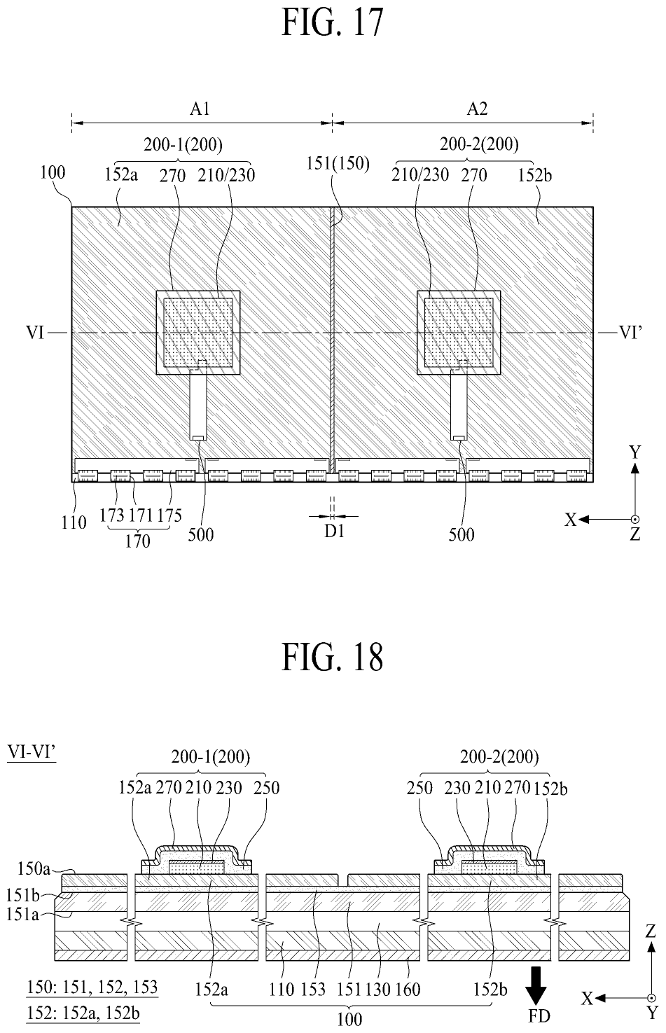

FIG. 17 illustrates a vibration member and a rear surface of a display panel, in a display apparatus according to another embodiment of the present disclosure. FIG. 18 is a cross-sectional view taken along line VI-VI′ illustrated in FIG. 17 according to another embodiment of the present disclosure. Particularly, FIGS. 17 and 18 illustrate an embodiment implemented by modifying the plate member described above with reference to FIGS. 7 and 8. In the following description, therefore, modified elements will be described in detail, the other elements are referred to by the same reference numerals as FIGS. 7 and 8, and repeated descriptions thereof can be omitted or will be briefly given.

With reference to FIGS. 17 and 18, in a display apparatus according to another embodiment of the present disclosure, a plate member 150 of a display panel 100 can include an internal plate 151 and a plurality of external plates 152.

The internal plate 151 can be substantially the same as the plate member 150 described above with reference to FIGS. 1 to 3, and thus, repeated descriptions thereof can be omitted or will be briefly given.

The internal plate 151 can be configured to cover a display part 130 of the display panel 100. The internal plate 151 can be attached to the display part 130 by an adhesive member. The adhesive member can be configured on a base member 110 to surround the display part 130. A first surface 151a of the internal plate 151 can be coupled (or adhered) to an adhesive member, or can be directly coupled (or adhered) to the adhesive member. The internal plate 151 can additionally or effectively dissipate heat occurring in the display panel 100, thereby minimizing a degradation in image quality caused by an afterimage which partially occurs due to heat occurring in the display panel 100. The internal plate 151 can protect a display part 130 or the display panel 100 from an external impact and can prevent external water or moisture from penetrating into a light-emitting device layer. The internal plate 151 can compensate for the stiffness of the display panel 100. For example, the internal plate 151 can be an internal conductive plate, an internal heat dissipation member, an internal heat dissipation plate, an internal heat dissipation substrate, an encapsulation substrate, an encapsulation plate, a stiff plate, a second substrate, a rear substrate, a rear member, a rear plate, an internal substrate, or an internal plate, but embodiments of the present disclosure are not limited thereto.

The plurality of external plates 152 can be configured to be connected or coupled to the internal plate 151. The plurality of external plates 152 can be configured to be separated from or electrically disconnected to one another at a rear surface (or a second surface) 151b of the internal plate 151. The plurality of external plates 152 can be configured to additionally dissipate heat of the internal plate 151. For example, the plurality of external plates 152 can be configured to have a thickness which is relatively thinner than the internal plate 151.

According to an embodiment of the present disclosure, the plurality of external plates 152 can be configured as one or more materials of an alloy of iron and nickel, stainless steel, aluminum (Al), a magnesium (Mg), a Mg alloy, a magnesium-lithium (Mg—Li) alloy, and an Al alloy, but embodiments of the present disclosure are not limited thereto. For example, the plurality of external plates 152 can be configured as one or more materials, which differ from that of the internal plate 151, of an alloy of Fe and Ni, stainless steel, aluminum (Al), a magnesium (Mg), a Mg alloy, a magnesium-lithium (Mg—Li) alloy, and an Al alloy. For example, the plurality of external plates 152 can include Al or an Al alloy.

The plate member 150 or the plurality of external plates 152 according to an embodiment of the present disclosure can include a first external plate 152a and a second external plate 152b.

The first external plate 152a can be connected to or coupled to a first region of the inner plate 151 corresponding to a first region A1 of the display panel 100. The second outer plate 152b can be connected to or coupled to a second region of the inner plate 151 corresponding to a second region A2 of the display panel 100.

Each of the first external plate 152a and the second external plate 152b can be coupled to the rear surface (or the second surface) 151b of the internal plate 151 by a coupling member 153.

The coupling member 153 can be disposed at a region between the internal plate 151 and each of the first external plate 152a and the second external plate 152b.

The coupling member 153 according to an embodiment of the present disclosure can include an adhesive material which is good in adhesive force or attaching force between the internal plate 151 and each of the first external plate 152a and the second external plate 152b. For example, the coupling member 153 can include an acrylic-based or urethane-based adhesive material, but embodiments of the present disclosure are not limited thereto. For example, the coupling member 153 can be an acrylic-based adhesive member having a characteristic where an adhesive force is relatively good and hardness is high, so that a vibration of the vibration member 200 is well transferred to the internal plate 151. The coupling member 153 can include a double-sided foam adhesive pad including an acrylic-based adhesive layer or an acrylic-based adhesive resin curing layer. For example, the adhesive layer of the coupling member 153 can further include an additive, such as a tackifier, a wax component, an anti-oxidation agent, or the like.

The coupling member 153 according to another embodiment of the present disclosure can include a pressure sensitive adhesive (PSA), an optically clear adhesive (OCA), or an optically clear resin (OCR). For example, the coupling member 153 can further include a vibration transfer medium. For example, the vibration transfer medium can decrease the loss of a vibration transferred to the internal plate 151. For example, the vibration transfer medium can include a piezoelectric material which is contained in or added to the coupling member 153, but embodiments of the present disclosure are not limited thereto.

The coupling member 153 according to another embodiment of the present disclosure can further include a hollow portion provided between the first external plate 152a and the second external plate 152b. The hollow portion of the coupling member 153 can provide an air gap between the internal plate 151 and each of the first external plate 152a and the second external plate 152b. Due to the air gap, a sound wave (or a sound pressure) based on a vibration of the vibration member 200 may not be dispersed by the coupling member 153, and can concentrate on the internal plate 151. Thus, the loss of a vibration caused by the coupling member 153 can be minimized.

The first external plate 152a and the second external plate 152b can be spaced apart from each other in a center region between the first region A1 and the second region A2 of the display panel 100. A separation distance D1 between the first external plate 152a and the second external plate 152b can be 3 cm or more. For example, the separation distance D1 between the first external plate 152a and the second external plate 152b can be 3 cm or more so that each of the first external plate 152a and the second external plate 152b vibrates individually (or independently). For example, when the separation distance D1 between the first external plate 152a and the second external plate 152b is less than 3 cm, a sound characteristic and/or a sound pressure level characteristic can be reduced due to interference between a vibration of the first external plate 152a and a vibration of the second external plate 152b occurring based on a vibration of the vibration member 200.

The vibration member 200 can be configured to vibrate each of the plurality of external plates 152a and 152b. For example, the vibration member 200 can be configured to use each of the plurality of external plates 152a and 152b as an electrode. For example, the vibration member 200 can be configured to vibrate individually (or independently) each of the first external plate 152a and the second external plate 152b. For example, the vibration member 200 can be configured to use each of the first external plate 152a and the second external plate 152b as an electrode. For example, the vibration member 200 can include a first vibration member 200-1 configured at a rear surface of the first external plate 152a and a second vibration member 200-2 configured at a rear surface of the second external plate 152b.

Except for that the first vibration member 200-1 and the second vibration member 200-2 are respectively provided at rear surfaces of the first external plate 152a and the second external plate 152b, the first vibration member 200-1 and the second vibration member 200-2 can be substantially the same as the first vibration member 200-1 and the second vibration member 200-2 described above with reference to FIG. 7, respectively, and thus, repeated descriptions thereof can be omitted or will be briefly given.

The first vibration member 200-1 can include a vibration layer 210 and a second electrode 230. The vibration layer 210 of the first vibration member 200-1 can be formed or coated on a rear surface of the first external plate 152a, and then, can be molded. The second electrode 230 of the first vibration member 200-1 can be configured to have the same shape and size as those of the vibration layer 210. The first vibration member 200-1 can further include a cover member 270 which is configured to cover the vibration layer 210 and the second electrode 230. As an embodiment of the present disclosure, the vibration layer 210 of the first vibration member 200-1 can vibrate based on a first vibration driving signal applied to the first external plate 152a and a second vibration driving signal applied to the second electrode 230, and thus, can vibrate the first external plate 152a and the first region A1 of the display panel 100, thereby outputting a first sound. As another embodiment of the present disclosure, the vibration layer 210 of the first vibration member 200-1 can vibrate based on the first vibration driving signal applied to the first external plate 152a and the second vibration driving signal applied to the second electrode 230 through a signal cable 500, and thus, can vibrate the first external plate 152a and the first region A1 of the display panel 100, thereby outputting the first sound.

The second vibration member 200-2 can include a vibration layer 210 and a second electrode 230. The vibration layer 210 of the second vibration member 200-2 can be formed or coated on a rear surface of the second external plate 152b, and then, can be molded. The second electrode 230 of the second vibration member 200-2 can be configured to have the same shape and size as those of the vibration layer 210. The second vibration member 200-2 can further include a cover member 270 which is configured to cover the vibration layer 210 and the second electrode 230. As an embodiment of the present disclosure, the vibration layer 210 of the second vibration member 200-2 can vibrate based on a first vibration driving signal applied to the second external plate 152b and a second vibration driving signal applied to the second electrode 230, and thus, can vibrate the second external plate 152b and the second region A2 of the display panel 100, thereby outputting a second sound. As another embodiment of the present disclosure, the vibration layer 210 of the second vibration member 200-2 can vibrate based on the first vibration driving signal applied to the second external plate 152b and the second vibration driving signal applied to the second electrode 230 through a signal cable 500, and thus, can vibrate the second external plate 152b and the second region A2 of the display panel 100, thereby outputting the first sound.

The first vibration member 200-1 and the second vibration member 200-2 can be configured to be horizontally symmetric with each other with respect to a center between the first region A1 and the second region A2 of the display panel 100, but embodiments of the present disclosure are not limited thereto and can be configured to be horizontally asymmetric.

The vibration member 200 described above with reference to FIGS. 9A to 12 can be identically applied to the vibration member 200 described above with reference to FIGS. 17 and 18. For example, the vibration member 200 described above with reference to FIGS. 17 and 18 can be configured to be substantially equal to the vibration member 200 described above with reference to FIGS. 9A to 12, and thus, repeated descriptions thereof can be omitted.

Like the display apparatus described above with reference to FIGS. 1 to 6, the display apparatus according to another embodiment of the present disclosure can output a sound in a forward direction FD of the display panel 100, and a thickness thereof can be reduced or slimmed. Also, the display apparatus according to another embodiment of the present disclosure can include the internal plate 151 and the plurality of external plates 152 of the plate member 150, and thus, can more effectively dissipate heat occurring in the display panel 100, thereby minimizing a degradation in image quality caused by an afterimage which partially occurs due to heat occurring in the display panel 100. Further, the display apparatus according to another embodiment of the present disclosure can output a two-channel stereo sound in the forward direction of the display panel 100, based on left and right division vibrations of the display panel 100 based on vibrations of the first and second vibration members 200-1 and 200-2 configured at each of the first external plate 152a and the second external plate 152b.

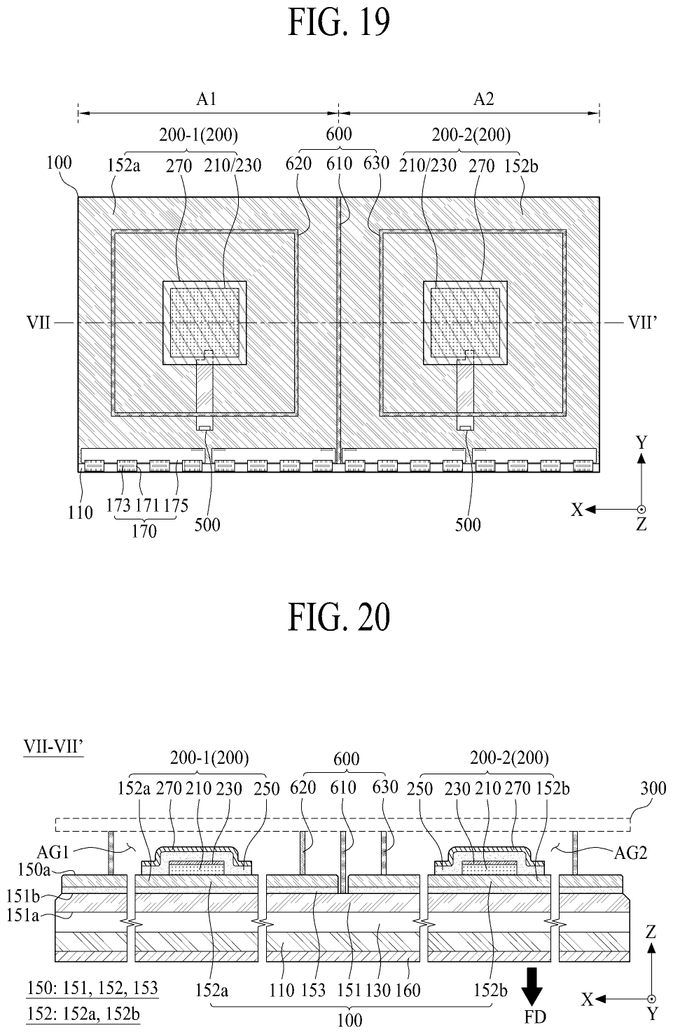

FIG. 19 illustrates a vibration member and a rear surface of a display panel, in a display apparatus according to another embodiment of the present disclosure. FIG. 20 is a cross-sectional view taken along line VII-VII′ illustrated in FIG. 19. Particularly, FIGS. 19 and 20 illustrate an embodiment of the present disclosure where a partition is further configured in the display apparatus described above with reference to FIGS. 17 and 18. In the following description, therefore, the partition and elements relevant thereto will be described in detail, the other elements are referred to by the same reference numerals as FIGS. 7 and 8, and repeated descriptions thereof can be omitted or will be briefly given.

With reference to FIGS. 19 and 20, the display apparatus according to another embodiment of the present disclosure can further include a partition 600 for dividing a first region A1 and a second region A2 of a display panel 100.

The display panel 100 can include regions A1 and A2 divided to correspond to each of the plurality of external plates 152 of the plate member 150. For example, the display panel 100 can include a first region A1 overlapping the first external plate 152a of the plate member 150 and a second region A2 overlapping the second external plate 152b of the plate member 150.

The partition 600 can be an air gap or a space, where sounds are generated when the display panel 100 is vibrated by the first and second vibration members 200-1 and 200-2. For example, the partition 600 can separate the sounds or a channel and can minimize or prevent or decrease the reduction of a sound characteristic caused by interference of the sounds. The partition 600 can be disposed at a region between the display panel 100 and the supporting member 300. For example, the partition 600 can be disposed at a region between a rear surface of the display panel 100 and a front surface of the supporting member 300. The partition 600 can be disposed at the supporting member 300 in order to minimize or reduce the effect of the image quality on the display panel 100 due to the partition 600. The partition 600 can be referred to as a sound blocking member, a sound separation member, a space separation member, an enclosure, or a baffle, or the like, but the terms are not limited thereto.

The partition 600 according to an embodiment of the present disclosure can include a partition member (or a first partition member) 610 which is disposed at a region between the first and second vibration members 200-1 and 200-2.

The partition member 610 can be disposed at a region between the first region A1 and the second region A2 of the display panel 100. The partition member 610 can be disposed at a region between an internal plate 151 of the plate member 150 and the supporting member 300 between the first region A1 and the second region A2 of the display panel 100. For example, the partition member 610 can be disposed at a region between a second surface of the internal plate 151 and the supporting member 300 corresponding to a center region between the first region A1 and the second region A2 of the display panel 100. The partition member 610 can separate the first sound generated by the first vibration member 200-1 and the second sound generated by the second vibration member 200-2. For example, the partition member 610 can block the transfer of a vibration generated in the first region A1 of the display panel 100 by the first vibration member 200-1 to the second region A2 of the display panel 100, or can block the transfer of a vibration generated in the second region A2 of the display panel 100 by the second vibration member 200-2 to the first region A1 of the display panel 100. Therefore, the partition member 610 can attenuate or absorb a vibration of the display panel 100 at a center of the display panel 100, and thus, the partition member 610 can block the transfer of a sound in the first region A1 to the second region A2, or can block the transfer of a sound in the second region A2 to the first region A1. Accordingly, the partition member 610 can separate a left sound and a right sound to further enhance a sound output characteristic of the display apparatus. Thus, the display apparatus according to an embodiment of the present disclosure can output a stereo sound including a two-channel form or a two-channel sound to the forward direction of the display panel 100 by separating the left and right sounds by the partition member 610.

The partition 600 according to an embodiment of the present disclosure can include a second partition member 620 surrounding the first vibration member 200-1 and a third partition member 630 surrounding the second vibration member 200-2.

The second partition member 620 can be disposed at a region between the first region A1 of the display panel 100 and the supporting member 300 to surround the first vibration member 200-1. The second partition member 620 can be disposed at a region between a first external plate 152a of the plate member 150 corresponding to the first region A1 of the display panel 100 and the supporting member 300 to be spaced apart from the first vibration member 200-1 to have a certain distance. The second partition member 620 can form a first air gap AG1 between the first external plate 152a and the supporting member 300 surrounding the first vibration member 200-1. For example, the second partition member 620 can define or limit a vibration region (or vibration area) of the first region A1 of the display panel 100 based on the first vibration member 200-1.

The third partition member 630 can be disposed at a region between the second region A2 of the display panel 100 and the supporting member 300 to surround the second vibration member 200-2. The third partition member 630 can be disposed at a region between a second external plate 152b of the plate member 150 corresponding to the second region A2 of the display panel 100 and the supporting member 300 to be spaced apart from the second vibration member 200-2 to have a certain distance. The third partition member 630 can form a second air gap AG2 between the second external plate 152b and the supporting member 300 surrounding the second vibration member 200-2. For example, the third partition member 630 can define or limit a vibration region (or vibration area) of the second region A2 of the display panel 100 based on the second vibration member 200-2.

The first air gap AG1 and the second air gap AG2 can be referred to as a sound separation space, a sound blocking space, or a sound interference prevention space, but embodiments of the present disclosure are not limited thereto.

Except for the arrangement that the second partition member 620 and the third partition member 630 are respectively disposed at a region between the external plate 152 of the plate member 150 and the supporting member 300, the second partition member 620 and the third partition member 630 can be substantially the same as the second partition member 620 and the third partition member 630 described above with reference to FIGS. 7 and 8, and thus, repeated descriptions thereof can be omitted.

The first vibration member 200-1 and the second vibration member 200-2 can be configured to be horizontally symmetric with each other with respect to a center between the first region A1 and the second region A2 of the display panel 100, but embodiments of the present disclosure are not limited thereto and can be configured to be horizontally asymmetric.

The vibration member 200 described above with reference to FIGS. 9A to 12 can be identically applied to the vibration member 200 described above with reference to FIGS. 19 and 20. For example, the vibration member 200 described above with reference to FIGS. 19 and 20 can be configured to be substantially equal to the vibration member 200 described above with reference to FIGS. 9A to 12, and thus, repeated descriptions thereof can be omitted.

Like the display apparatus described above with reference to FIGS. 17 and 18, the display apparatus according to another embodiment of the present disclosure can output a sound in a forward direction FD of the display panel 100, and a thickness thereof can be reduced or slimmed, and can more effectively dissipate heat occurring in the display panel 100, thereby minimizing a degradation in image quality caused by an afterimage which partially occurs due to heat occurring in the display panel 100. Further, the display apparatus according to another embodiment of the present disclosure can output a stereo sound including a two-channel form or a two-channel sound to the forward direction of the display panel 100 by separating the left and right sounds according to one or more of the partition member 610, and the second and third partition members 620 and 630.

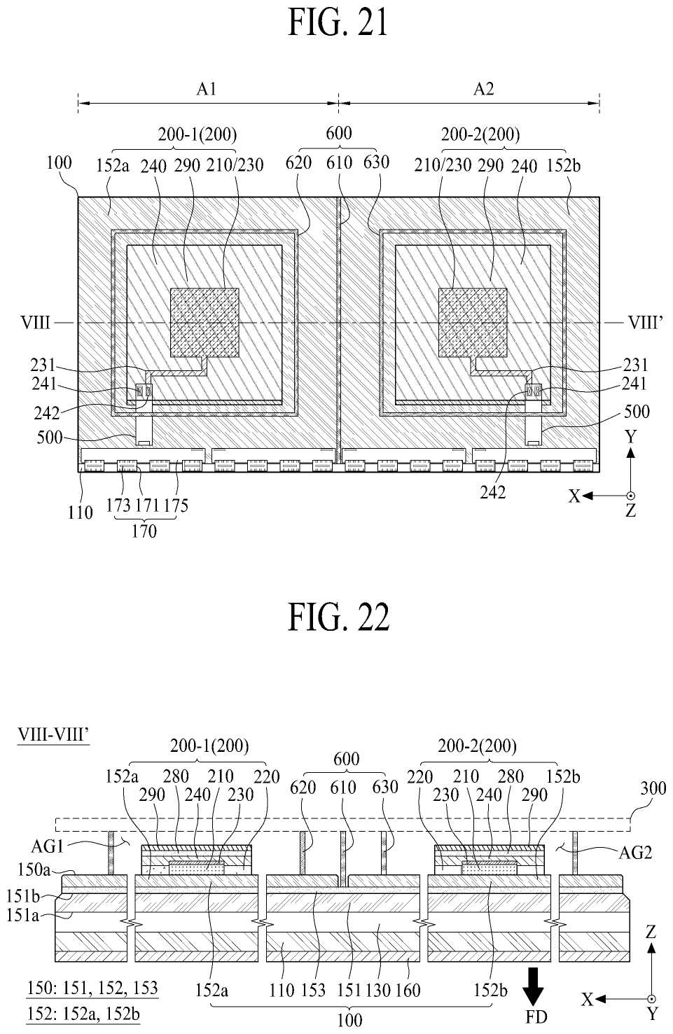

FIG. 21 illustrates a vibration member and a rear surface of a display panel, in a display apparatus according to another embodiment of the present disclosure. FIG. 22 is a cross-sectional view taken along line VIII-VIII′ illustrated in FIG. 21 according to another embodiment of the present disclosure. Particularly, FIGS. 21 and 22 illustrate an embodiment implemented by modifying the vibration member described above with reference to FIG. 17 or 18. In the following description, therefore, modified elements will be described in detail, the other elements are referred to by the same reference numerals as FIGS. 15 and 16, and repeated descriptions thereof can be omitted or will be briefly given.

With reference to FIGS. 21 and 22, in a display apparatus according to another embodiment of the present disclosure, a vibration member 200 can include a first vibration member 200-1 and a second vibration member 200-2.

The first vibration member 200-1 can use a first external plate 152a of a plate member 150 of a display panel 100 as a first electrode. For example, the first external plate 152a of the plate member 150 can function as the first electrode of the vibration member 200.

The first vibration member 200-1 can include a vibration layer 210, an insulation layer 220, a second electrode 230, and a protection layer 240.

The vibration layer 210, the insulation layer 220, the second electrode 230, and the protection layer 240 of the first vibration member 200-1 can be substantially the same as each of the vibration layer 210, the insulation layer 220, the second electrode 230, and the protection layer 240 of the vibration member 200 described above with reference to FIGS. 13 and 14, and thus, repeated descriptions thereof can be omitted.

The insulation layer 220 of the first vibration member 200-1 can be disposed at a second surface 150a of the first external plate 152a at a periphery of (or around) the vibration layer 210. For example, the insulation layer 220 of the first vibration member 200-1 can be disposed at the second surface 150a of the first external plate 152a to surround each lateral surfaces of the vibration layer 210. For example, the insulation layer 220 of the first vibration member 200-1 can be disposed at a portion or an entire of the other portion, except a disposition region of the vibration layer 210, of the second surface 150a of the first external plate 152a.

The second electrode 230 of the first vibration member 200-1 can be configured at or coupled to a second surface 210a of the vibration layer 210. The second electrode 230 of the first vibration member 200-1 can have the same size as that of the vibration layer 210, or can have a size which is smaller than that of the vibration layer 210. The second electrode 230 of the first vibration member 200-1 can further include an extension line (or one or more extension lines) 231.

The protection layer 240 of the first vibration member 200-1 can be configured to protect the insulation layer 220 and the second electrode 230. For example, the protection layer 240 of the first vibration member 200-1 can be configured to protect the first vibration member 200-1. For example, the protective layer 240 of the first vibration member 200-1 can include a first hole 241 and a second hole 242, which are configured in parallel with each other at the protective layer 240 overlapping each of a portion of the first external plate 152a and a portion of the extension line 231. Accordingly, each of a portion of the first external plate 152a and a portion of the extension line 231 can be electrically coupled to the signal cable 500 through each of the first hole 241 and the second hole 242.

The second vibration member 200-2 can use a second external plate 152b of the plate member 150 of the display panel 100 as a first electrode. For example, the second external plate 152b of the plate member 150 can function as the first electrode of the vibration member 200.

The second vibration member 200-2 can include a vibration layer 210, an insulation layer 220, a second electrode 230, and a protection layer 240.

The vibration layer 210, the insulation layer 220, the second electrode 230, and the protection layer 240 of the second vibration member 200-2 can be substantially the same as each of the vibration layer 210, the insulation layer 220, the second electrode 230, and the protection layer 240 of the vibration member 200 described above with reference to FIGS. 13 and 14, and thus, repeated descriptions thereof can be omitted.

The insulation layer 220 of the second vibration member 200-2 can be disposed at a second surface 150a of the second external plate 152b at a periphery of (or around) the vibration layer 210. For example, the insulation layer 220 of the second vibration member 200-2 can be disposed at the second surface 150a of the second external plate 152b to surround each lateral surfaces of the vibration layer 210. For example, the insulation layer 220 of the second vibration member 200-2 can be disposed at a portion or an entire of the other portion, except a disposition region of the vibration layer 210, of the second surface 150a of the second external plate 152b.

The second electrode 230 of the second vibration member 200-2 can be configured at or coupled to a second surface 210a of the vibration layer 210. The second electrode 230 of the second vibration member 200-2 can have the same size as that of the vibration layer 210, or can have a size which is smaller than that of the vibration layer 210. The second electrode 230 of the second vibration member 200-2 can further include an extension line (or one or more extension lines) 231.

The protection layer 240 of the second vibration member 200-2 can be configured to protect the insulation layer 220 and the second electrode 230. For example, the protection layer 240 of the second vibration member 200-2 can be configured to protect the second vibration member 200-2. For example, the protective layer 240 of the second vibration member 200-2 can include a first hole 241 and a second hole 242, which are configured in parallel with each other at the protective layer 240 overlapping each of a portion of the second external plate 152b and a portion of the extension line 231. Accordingly, each of a portion of the second external plate 152b and a portion of the extension line 231 can be electrically coupled to the signal cable 500 through each of the first hole 241 and the second hole 242.

The display apparatus or each of the first and second vibration members 200-1 and 200-2 according to another embodiment of the present disclosure can further include a cover member 290.

The cover member 290 of the first vibration member 200-1 can be configured to cover the protection layer 240 and a portion of the signal cable 500. The cover member 290 of the first vibration member 200-1 can be connected or coupled to the protection layer 240 and a portion of the signal cable 500 by an adhesive layer 280. The cover member 290 of the second vibration member 200-2 can be configured to cover the protection layer 240 and a portion of the signal cable 500. The cover member 290 of the second vibration member 200-2 can be connected or coupled to the protection layer 240 and a portion of the signal cable 500 by an adhesive layer 280. The cover member 290 and the adhesive layer 280 of each of the first and second vibration member 200-1 and 200-2 can be substantially the same as each of the cover member 290 and the adhesive layer 280 described above with reference to FIGS. 15 and 16, and thus, repeated descriptions thereof can be omitted.

Like the display apparatus described above with reference to FIGS. 17 to 20, the display apparatus according to another embodiment of the present disclosure can output a sound in a forward direction FD of the display panel 100, and a thickness of the display apparatus can be reduced or slimmed, and can more effectively dissipate heat occurring in the display panel 100, thereby minimizing a degradation in image quality caused by an afterimage which partially occurs due to heat occurring in the display panel 100. Further, like the display apparatus described above with reference to FIGS. 13 to 16, in the display apparatus according to another embodiment of the present disclosure, the pad part of the vibration member 200 can be disposed at a peripheral region, which does not overlap the vibration layer 210, of the vibration member 200, and thus, a coupling process between the pad part of the vibration member 200 and the signal cable 500 can be easily performed.

The display apparatus according to another embodiment of the present disclosure can further include a partition 600 for dividing the first region A1 and the second region A2 of the display panel 100.

The partition 600 can be substantially the same as the partition 600 described above with reference to FIGS. 19 and 20, and thus, repeated descriptions thereof can be omitted.

The partition 600 according to an embodiment of the present disclosure can include a partition member (or a first partition member) 610 which is disposed at a region between the first and second vibration members 200-1 and 200-2. For example, the partition member 610 can be disposed at a region between an internal plate 151 of the plate member 150 and the supporting member 300 between the first region A1 and the second region A2 of the display panel 100.

The partition 600 according to an embodiment of the present disclosure can include a second partition member 620 surrounding the first vibration member 200-1 and a third partition member 630 surrounding the second vibration member 200-2.

The second partition member 620 can be disposed at a region between the first region A1 of the display panel 100 and the supporting member 300 to surround the first vibration member 200-1. The second partition member 620 can form a first air gap AG1 between the first external plate 152a and the supporting member 300 surrounding the first vibration member 200-1.

The third partition member 630 can be disposed at a region between the second region A2 of the display panel 100 and the supporting member 300 to surround the second vibration member 200-2. The third partition member 630 can form a second air gap AG2 between the second external plate 152b and the supporting member 300 surrounding the second vibration member 200-2.

As described above, the display apparatus according to another embodiment of the present disclosure can output a stereo sound including a two-channel form or a two-channel sound to the forward direction of the display panel 100 by separating the left and right sounds according to one or more of the partition member 610, and the second and third partition members 620 and 630.

The first vibration member 200-1 and the second vibration member 200-2 can be configured to be horizontally symmetric with each other with respect to a center between the first region A1 and the second region A2 of the display panel 100, but embodiments of the present disclosure are not limited thereto and can be configured to be horizontally asymmetric.

The vibration member 200 described above with reference to FIGS. 9A to 12 can be identically applied to the vibration member 200 described above with reference to FIGS. 21 and 22. For example, the vibration member 200 described above with reference to FIGS. 21 and 22 can be configured to be substantially equal to the vibration member 200 described above with reference to FIGS. 9A to 12, and thus, repeated descriptions thereof can be omitted.

A display apparatus according to one or more embodiments of the present disclosure are described below.

A display apparatus according to one or more embodiments of the present disclosure can comprise a display panel including a base member, a plate member, and a display part between the base member and the plate member, a vibration layer at a rear surface of the plate member, and an electrode layer at the vibration layer.

According to one or more embodiments of the present disclosure, the vibration layer can be configured to vibrate based on a signal applied to the plate member and the electrode layer.

According to one or more embodiments of the present disclosure, the display apparatus can further comprise a cover member on the electrode layer.

According to one or more embodiments of the present disclosure, the display apparatus can further comprise an adhesive layer between the electrode layer and the cover member.

According to one or more embodiments of the present disclosure, the display apparatus can further comprise a signal cable electrically coupled to the plate member and the electrode layer.

According to one or more embodiments of the present disclosure, the display apparatus can further comprise a cover member covering a portion of the signal cable and the electrode layer.

According to one or more embodiments of the present disclosure, the signal cable can comprise a first contact line electrically coupled to the plate member, and a second contact line electrically coupled to the electrode layer.

According to one or more embodiments of the present disclosure, a portion of the signal cable including the first contact line and the second contact line can be accommodated into an adhesive layer between the plate member and the cover member.

According to one or more embodiments of the present disclosure, the display apparatus can further comprise an insulation layer at the plate member at a periphery of the vibration layer, and a protection layer configured to cover the electrode layer and the insulation layer.

According to one or more embodiments of the present disclosure, the insulation layer can surround the vibration layer. An uppermost surface of the insulation layer can be under an uppermost surface of the vibration layer.

According to one or more embodiments of the present disclosure, the display apparatus can further comprise an extension line extending from one side of the electrode layer onto the insulation layer.

According to one or more embodiments of the present disclosure, the display apparatus can further comprise a signal cable electrically coupled to the plate member and the extension line.

A display apparatus according to one or more embodiments of the present disclosure can comprise a display panel including a base member, a plate member, and a display part between the base member and the plate member, the display panel configured to output a sound based on a vibration, a vibration member provided at the plate member, and a signal cable electrically coupled to the plate member and the vibration member.

According to one or more embodiments of the present disclosure, the vibration member can be configured to vibrate based on a signal applied thereto through or by the plate member and the signal cable.

According to one or more embodiments of the present disclosure, the vibration member can comprise a vibration layer at a rear surface of the plate member, and a second electrode at the vibration layer. The plate member can be a first electrode of the vibration member.

According to one or more embodiments of the present disclosure, the signal cable can be electrically coupled to the plate member and the second electrode.

According to one or more embodiments of the present disclosure, the display apparatus can further comprise a cover member configured to cover the vibration member, and an adhesive layer between the vibration member and the cover member.

According to one or more embodiments of the present disclosure, a portion of the signal cable adjacent to the vibration layer can be accommodated into another adhesive layer between the plate member and the cover member.

According to one or more embodiments of the present disclosure, the vibration member can comprise a vibration layer at a rear surface of the plate member, an insulation layer at a periphery of the vibration layer, a second electrode at the vibration layer, an extension line extending from one side of the second electrode onto the insulation layer, and a protection layer covering the second electrode and the extension line.

According to one or more embodiments of the present disclosure, the signal cable can be electrically coupled to the plate member and the extension line.

According to one or more embodiments of the present disclosure, the display panel can comprise a first region and a second region, and the vibration member can comprise a first vibration member at the first region, and a second vibration member at the second region.

According to one or more embodiments of the present disclosure, each of the first vibration member and the second vibration member can comprise one or more vibration layers at a rear surface of the plate member, and one or more second electrodes at the one or more vibration layers. The plate member can be a first electrode of each of the first vibration member and the second vibration member.

According to one or more embodiments of the present disclosure, each of the first vibration member and the second vibration member can comprise one or more vibration layers at a rear surface of the plate member, an insulation layer at a periphery of the one or more vibration layers, one or more second electrodes at the one or more vibration layers, one or more extension lines extending from one side of each of the one or more second electrodes onto the insulation layer, and a protection layer covering the second electrode and the one or more extension lines.

According to one or more embodiments of the present disclosure, the display apparatus can further comprise a partition configured to divide the first region and the second region of the display panel.

According to one or more embodiments of the present disclosure, the display apparatus can further comprise a supporting member at a rear surface of the plate member, the partition can comprise one or more of first to third partition members, the first partition member can be between the plate member and the supporting member in a region between the first region and the second region of the display panel, the second partition member can be between the plate member and the supporting member to surround the first vibration member, and the third partition member can be between the plate member and the supporting member to surround the second vibration member.

According to one or more embodiments of the present disclosure, the plate member can comprise an internal plate coupled to the display part, a first external plate coupled to a first region of the internal plate corresponding to the first region of the display panel, and a second external plate coupled to the second region of the internal plate corresponding to a second region of the display panel and spaced apart from the first external plate.

According to one or more embodiments of the present disclosure, the first vibration member can be configured to vibrate based on a signal applied thereto through the first external plate and the signal cable, and the second vibration member can be configured to vibrate based on a signal applied thereto through the second external plate and the signal cable.

According to one or more embodiments of the present disclosure, the first vibration member can comprise one or more vibration layers at a rear surface of the first external plate, and one or more second electrodes at the one or more vibration layers, and the first external plate can be a first electrode of the first vibration member.

According to one or more embodiments of the present disclosure, the second vibration member can comprise one or more vibration layers at a rear surface of the second external plate, and one or more second electrodes at the one or more vibration layers, and the second external plate can be a first electrode of the second vibration member.

According to one or more embodiments of the present disclosure, the first vibration member can comprise one or more vibration layers at a rear surface of the first external plate, an insulation layer at a periphery of the one or more vibration layers, one or more second electrodes at the one or more vibration layers, one or more extension lines extending from one side of the one or more second electrodes onto the insulation layer, and a protection layer configured to cover the one or more second electrodes and the one or more extension lines, and the first external plate can be a first electrode of the first vibration member.

According to one or more embodiments of the present disclosure, the second vibration member can comprise one or more vibration layers at a rear surface of the second external plate, an insulation layer at a periphery of the one or more vibration layers, one or more second electrodes at the one or more vibration layers, one or more extension lines extending from one side of the one or more second electrodes onto the insulation layer, and a protection layer configured to cover the one or more second electrodes and the one or more extension lines, and the second external plate can be a first electrode of the second vibration member.

According to one or more embodiments of the present disclosure, the display apparatus can further comprise a partition configured to divide the first region and the second region of the display panel.

According to one or more embodiments of the present disclosure, the display apparatus can further comprise a supporting member at a rear surface of the plate member, the partition can comprise one or more of first to third partition members, the first partition member can be between the internal plate and the supporting member in a region between the first region and the second region of the display panel, the second partition member can be disposed between the first external plate and the supporting member to surround the first vibration member, and the third partition member can be disposed between the second external plate and the supporting member to surround the second vibration member.

According to one or more embodiments of the present disclosure, the signal cable can be electrically coupled to the plate member and the one or more second electrodes.

According to one or more embodiments of the present disclosure, the vibration member can further comprise a third vibration member at a periphery portion of the first region of the display panel, and including a shape being different from a shape of the first vibration member, and a fourth vibration member at a periphery portion of the second region of the display panel, and including a shape being different from a shape of the second vibration member.

According to one or more embodiments of the present disclosure, the vibration layer can comprise a three or more-angled polygonal shape, a circular shape, or an oval shape.

According to one or more embodiments of the present disclosure, the vibration layer has a non-tetragonal shape including one or more of one or more straight lines and one or more curves having a curvature.

According to one or more embodiments of the present disclosure, the vibration layer can comprise a piezoelectric material.

According to one or more embodiments of the present disclosure, the display part can comprise a plurality of pixels configured to output light toward the base member based on light emitted from a light-emitting device layer.

According to one or more embodiments of the present disclosure, the plate member can include one or more materials of an alloy of iron and nickel, stainless steel, aluminum, magnesium, a magnesium alloy, a magnesium-lithium alloy, and an aluminum alloy.

A vibration member (or a vibration apparatus) according to one or more embodiments of the present disclosure can be applied to an apparatus or a display apparatus. The apparatus or display apparatus according to one or more embodiments of the present disclosure can be applied to mobile apparatuses, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theater apparatuses, theater display apparatuses, TVs, wall paper display apparatuses, signage apparatuses, game machines, notebook computers, monitors, cameras, camcorders, and home appliances, or the like. In addition, when an apparatus or display apparatus according to one or more embodiments of the present disclosure is applied to a mobile device, or the like, the vibration member (or the vibration apparatus) can be one or more of a speaker, a receiver, and a haptic device, but embodiments of the present disclosure are not limited thereto.

It will be apparent to those skilled in the art that various modifications and variations can be made in the present disclosure without departing from the scope of the disclosures. Thus, it is intended that the present disclosure covers the modifications and variations of this disclosure provided they come within the scope of the appended claims and their equivalents.

What is claimed is:

1. A display apparatus, comprising:
a display panel including a base member, a plate member, and a display part disposed between the base member and the plate member;
a vibration layer at a rear surface of the plate member; and
an electrode layer at the vibration layer.

2. The display apparatus of claim 1, wherein the vibration layer is configured to vibrate based on a signal applied to the plate member and the electrode layer.

3. The display apparatus of claim 1, further comprising a cover member on the electrode layer.

4. The display apparatus of claim 3, further comprising an adhesive layer disposed between the electrode layer and the cover member.

5. The display apparatus of claim 1, further comprising a signal cable electrically coupled to the plate member and the electrode layer.

6. The display apparatus of claim 5, further comprising a cover member covering a portion of the signal cable and the electrode layer.

7. The display apparatus of claim 6, wherein the signal cable comprises:
a first contact line electrically coupled to the plate member; and
a second contact line electrically coupled to the electrode layer.

8. The display apparatus of claim 7, wherein a portion of the signal cable including the first contact line and the second contact line is accommodated into an adhesive layer disposed between the plate member and the cover member.

9. The display apparatus of claim 1, further comprising:
an insulation layer disposed at the plate member at a periphery of the vibration layer; and
a protection layer configured to cover the electrode layer and the insulation layer.

10. The display apparatus of claim 9, wherein the insulation layer surrounds the vibration layer, and
wherein an uppermost surface of the insulation layer is disposed under an uppermost surface of the vibration layer.

11. The display apparatus of claim 9, further comprising an extension line extending from one side of the electrode layer onto the insulation layer.

12. The display apparatus of claim 11, further comprising a signal cable electrically coupled to the plate member and the extension line.

13. A display apparatus, comprising:
a display panel including a base member, a plate member, and a display part disposed between the base member and the plate member, the display panel configured to output a sound based on a vibration;
a vibration member provided at the plate member; and
a signal cable electrically coupled to the plate member and the vibration member.

14. The display apparatus of claim 13, wherein the vibration member is configured to vibrate based on a signal applied thereto by the plate member and the signal cable.

15. The display apparatus of claim 13, wherein the vibration member comprises:
a vibration layer at a rear surface of the plate member; and
a second electrode at the vibration layer, and
wherein the plate member is a first electrode of the vibration member.

16. The display apparatus of claim 15, wherein the signal cable is electrically coupled to the plate member and the second electrode.

17. The display apparatus of claim 15, further comprising:
a cover member configured to cover the vibration member; and
an adhesive layer disposed between the vibration member and the cover member.

18. The display apparatus of claim 17, wherein a portion of the signal cable adjacent to the vibration layer is accommodated into another adhesive layer disposed between the plate member and the cover member.

19. The display apparatus of claim 13, wherein the vibration member comprises:
a vibration layer at a rear surface of the plate member;
an insulation layer at a periphery of the vibration layer;
a second electrode at the vibration layer;
an extension line extending from one side of the second electrode onto the insulation layer; and
a protection layer covering the second electrode and the extension line.

20. The display apparatus of claim 19, wherein the signal cable is electrically coupled to the plate member and the extension line.

21. The display apparatus of claim 13, wherein the display panel comprises a first region and a second region, and
wherein the vibration member comprises:
a first vibration member at the first region; and
a second vibration member at the second region.

22. The display apparatus of claim 21, wherein each of the first vibration member and the second vibration member comprises:
one or more vibration layers at a rear surface of the plate member; and
one or more second electrodes at the one or more vibration layers, and
wherein the plate member is a first electrode of each of the first vibration member and the second vibration member.

23. The display apparatus of claim 21, wherein each of the first vibration member and the second vibration member comprises:
one or more vibration layers at a rear surface of the plate member;
an insulation layer at a periphery of the one or more vibration layers;
one or more second electrodes at the one or more vibration layers;
one or more extension lines extending from one side of each of the one or more second electrodes onto the insulation layer; and
a protection layer covering the second electrode and the one or more extension lines.

24. The display apparatus of claim 21, further comprising a partition configured to divide the first region and the second region of the display panel.

25. The display apparatus of claim 24, further comprising a supporting member at a rear surface of the plate member,
wherein the partition comprises one or more of first to third partition members,
wherein the first partition member is disposed between the plate member and the supporting member in a region disposed between the first region and the second region of the display panel,
wherein the second partition member is disposed between the plate member and the supporting member to surround the first vibration member, and
wherein the third partition member is disposed between the plate member and the supporting member to surround the second vibration member.

26. The display apparatus of claim 21, wherein the plate member comprises:
an internal plate coupled to the display part;
a first external plate coupled to a first region of the internal plate corresponding to the first region of the display panel; and
a second external plate coupled to a second region of the internal plate corresponding to the second region of the display panel and spaced apart from the first external plate.

27. The display apparatus of claim 26, wherein the first vibration member is configured to vibrate based on a signal applied thereto through the first external plate and the signal cable; and
wherein the second vibration member is configured to vibrate based on a signal applied thereto through the second external plate and the signal cable.

28. The display apparatus of claim 26, wherein the first vibration member comprises:
one or more vibration layers at a rear surface of the first external plate; and
one or more second electrodes at the one or more vibration layers, and
wherein the first external plate is a first electrode of the first vibration member.

29. The display apparatus of claim 26, wherein the second vibration member comprises:
one or more vibration layers at a rear surface of the second external plate; and
one or more second electrodes at the one or more vibration layers, and
wherein the second external plate is a first electrode of the second vibration member.

30. The display apparatus of claim 26, wherein the first vibration member comprises:
one or more vibration layers at a rear surface of the first external plate;
an insulation layer at a periphery of the one or more vibration layers;
one or more second electrodes at the one or more vibration layers;
one or more extension lines extending from one side of the one or more second electrodes onto the insulation layer; and
a protection layer configured to cover the one or more second electrodes and the one or more extension lines, and
wherein the first external plate is a first electrode of the first vibration member.

31. The display apparatus of claim 26, wherein the second vibration member comprises:
one or more vibration layers at a rear surface of the second external plate;
an insulation layer at a periphery of the one or more vibration layers;
one or more second electrodes at the one or more vibration layers;
one or more extension lines extending from one side of the one or more second electrodes onto the insulation layer; and
a protection layer configured to cover the one or more second electrodes and the one or more extension lines, and
wherein the second external plate is a first electrode of the second vibration member.

32. The display apparatus of claim 26, further comprising a partition configured to divide the first region and the second region of the display panel.

33. The display apparatus of claim 32, further comprising a supporting member at a rear surface of the plate member,
wherein the partition comprises one or more of first to third partition members,
wherein the first partition member is disposed between the internal plate and the supporting member in a region disposed between the first region and the second region of the display panel,
wherein the second partition member is disposed between the first external plate and the supporting member to surround the first vibration member, and
wherein the third partition member is disposed between the second external plate and the supporting member to surround the second vibration member.

34. The display apparatus of claim 22, wherein the signal cable is electrically coupled to the plate member and the one or more second electrodes.

35. The display apparatus of claim 21, wherein the vibration member further comprises:
a third vibration member at a periphery portion of the first region of the display panel, and including a shape being different from a shape of the first vibration member; and
a fourth vibration member at a periphery portion of the second region of the display panel, and including a shape being different from a shape of the second vibration member.

36. The display apparatus of claim 1, wherein the vibration layer has a three or more-angled polygonal shape, a circular shape, or an oval shape, or
wherein the vibration layer comprises a piezoelectric material.

37. The display apparatus of claim 1, wherein the vibration layer has a non-tetragonal shape including one or more of one or more straight lines and one or more curves having a curvature, or
wherein the vibration layer comprises a piezoelectric material.

38. The display apparatus of claim 1, wherein the display part comprises a plurality of pixels configured to output light toward the base member based on light emitted from a light-emitting device layer.

39. The display apparatus of claim 1, wherein the plate member includes one or more materials of an alloy of iron and nickel, stainless steel, aluminum, magnesium, a magnesium alloy, a magnesium-lithium alloy, and an aluminum alloy.
